(19) United States
(12) Patent Application Publication
(10) Pub. No.: US 2025/0158510 A1
(43) Pub. Date: May 15, 2025

(54) POWER SUPPLY DEVICE AND MEMORY MODULE INCLUDING THE SAME

(71) Applicant: Samsung Electronics Co., Ltd., Suwon-si (KR)

(72) Inventors: Jeongseop LEE, Suwon-si (KR); Kangyoon LEE, Seoul (KR)

(73) Assignees: Samsung Electronics Co., Ltd., Suwon-si (KR); RESEARCH & BUSINESS FOUNDATION SUNGKYUNKWAN UNIVERSITY, Gyeonggi-Do (KR)

(21) Appl. No.: 18/731,671

(22) Filed: Jun. 3, 2024

(30) Foreign Application Priority Data
Nov. 15, 2023 (KR) 10-2023-0157948

(51) Int. Cl. H02M 1/00; G11C 11/4074; H02M 3/07

(52) U.S. Cl. CPC H02M 1/0095; G11C 11/4074; H02M 3/07

(57) ABSTRACT

A power supply device includes a three-level converting circuit, a dual path hybrid converting circuit and an auxiliary switch circuit. The three-level converting circuit includes a flying capacitor for three-level operation, and generates an intermediate voltage based on an input voltage, a plurality of first control signals and the flying capacitor. The dual path hybrid converting circuit includes a first path, a second path, an inductor in the first path and a hybrid capacitor in the second path, and generates an output voltage based on the intermediate voltage, a second control signal, the inductor and the hybrid capacitor. The auxiliary switch circuit controls current flow through the hybrid capacitor based on a third control signal. The power supply device operates based on a four-phase scheme or a six-phase scheme depending on an operation mode.

### CROSS-REFERENCE TO RELATED APPLICATION

This application claims priority under 35 USC § 119 to Korean Patent Application No. 10-2023-0157948 filed on Nov. 15, 2023 in the Korean Intellectual Property Office (KIPO), the contents of which are herein incorporated by reference in their entirety.

### BACKGROUND

The present disclosure relates generally to semiconductor integrated circuits, and more particularly to power supply devices, and memory modules including the power supply devices.

Semiconductor memory devices may be divided into two categories depending upon whether or not they retain stored data when disconnected from a power supply. These categories include volatile memory devices, which lose stored data when disconnected from power, and nonvolatile memory devices, which retain stored data when disconnected from power. While volatile memory devices may perform read and write operations at a high speed, contents stored therein may be lost at power-off. Since nonvolatile memory devices retain contents stored therein even at power-off, they may be used to store data that needs to be retained.

There is an increasing demand for high-efficiency, regulated power supply devices in several market segments such as e.g., semiconductor memory devices, computing devices, charging devices, etc. Specifically, it is highly desirable to design power converters with higher efficiency and smaller area than conventional buck converters. With regard to the overall area of the power converter, the sizes of the required inductors are important design parameters. Thus, it is important to reduce the sizes of the inductors.

### SUMMARY

Some example embodiments of the present disclosure provide a power supply device capable of efficiently reducing loss due to increased direct current resistance (DCR) by reducing a physical size of an inductor.

Some example embodiments of the present disclosure provide a memory module including the power supply device.

Some example embodiments of the inventive concepts provide a power supply device that includes a three-level converting circuit, a dual path hybrid converting circuit and an auxiliary switch circuit. The three-level converting circuit includes a flying capacitor for three-level operation, the three-level converting circuit generating an intermediate voltage based on an input voltage, a plurality of first control signals and the flying capacitor. The dual path hybrid converting circuit includes a first path, a second path, an inductor in the second path and a hybrid capacitor in the second path, and the dual path hybrid converting circuit generates an output voltage based on the intermediate voltage, a second control signal, the inductor and the hybrid capacitor. Both the first path and the second path are connected to an output node providing the output voltage. The first path and the second path are different from each other. The auxiliary switch circuit is between the three-level converting circuit and the dual path hybrid converting circuit, and controls current flow through the hybrid capacitor based on a third control signal. The power supply device selectively operates based on a four-phase scheme and a six-phase scheme depending on an operation mode.

Some example embodiments of the inventive concepts further provide a memory module that includes a circuit board, a plurality of memory devices on the circuit board, and a power supply device on the circuit board. The power supply device provides a power supply voltage to the plurality of memory devices, and includes a three-level converting circuit, a dual path hybrid converting circuit and an auxiliary switch circuit. The three-level converting circuit includes a flying capacitor for three-level operation, and generates an intermediate voltage based on an input voltage, a plurality of first control signals and the flying capacitor. The dual path hybrid converting circuit includes a first path, a second path, an inductor in the first path and a hybrid capacitor in the second path, and generates an output voltage based on the intermediate voltage, a second control signal, the inductor and the hybrid capacitor. Both the first path and the second path are connected to an output node providing the output voltage. The first path and the second path are different from each other. The output voltage corresponds to the power supply voltage. The auxiliary switch circuit is between the three-level converting circuit and the dual path hybrid converting circuit, and controls a current flow through the hybrid capacitor based on a third control signal. The power supply device selectively operates based on a four-phase scheme and a six-phase scheme depending on an operation mode.

Some example embodiments of the inventive concepts still further provide a power supply device that includes a first transistor, a second transistor, a third transistor, a fourth transistor, a flying capacitor, an inductor, a hybrid capacitor, a fifth transistor, a sixth transistor and an output capacitor. The first transistor is connected between an input voltage and a first node. The second transistor is connected between the first node and a second node, the second node providing an intermediate voltage. The third transistor is connected between the second node and a third node. The fourth transistor is connected between the third node and a ground voltage. The flying capacitor is connected between the first node and the third node. The inductor is connected between the second node and an output node, the output node providing an output voltage. The hybrid capacitor is connected between the second node and a fourth node. The fifth transistor is connected between the fourth node and the output node. The sixth transistor is connected between the third node and the fourth node. A body bias voltage applied to the sixth transistor is changeable. The output capacitor is connected between the output node and the ground voltage. The first, second, third and fourth transistors and the flying capacitor perform three-level operation. The inductor is included in a first path, the first path being connected to the output node. The hybrid capacitor is included in a second path, the second path being connected to the output node. The power supply device generates the output voltage using a dual path including the first and second paths. The power supply device selectively operates based on a four-phase scheme and a six-phase scheme based on a conversion ratio obtained by dividing the output voltage by the input voltage.

The power supply device according to some example embodiments may include the flying capacitor for the three-level operation, as well as the inductor and the hybrid capacitor for the dual path operation. For example, the power supply device may be implemented in the form of a three-level dual path hybrid buck converter. The AC current component may be reduced by the three-level operation, and the DC current component may be reduced by the dual path operation. Accordingly, even in an environment where the physical size of the inductor is relatively small and the DC resistance of the inductor is relatively large, the loss due to the DC resistance may be reduced by reducing the RMS current of the inductor, and thus a decrease in the conversion efficiency may be limit and/or prevented.

### BRIEF DESCRIPTION OF THE DRAWINGS

Illustrative, non-limiting example embodiments will be more clearly understood from the following detailed description taken in conjunction with the accompanying drawings.

FIG. 1 is a block diagram illustrating a power supply device according to some example embodiments of the inventive concepts.

FIG. 2 is a circuit diagram illustrating a power supply device according to some example embodiments.

FIG. 3 is a circuit diagram illustrating an example of a power supply device of FIG. 2.

FIGS. 4, 5A, 5B, 5C, 5D, 6A and 6B are diagrams illustrating an operation of a power supply device of FIG. 3.

FIGS. 7A, 7B, 7C, 7D, 8A and 8B are diagrams illustrating performance of a power supply device of FIG. 3.

FIGS. 9, 10A, 10B, 10C, 10D, 10E, 10F, 11A and 11B are diagrams illustrating an operation of a power supply device of FIG. 3.

FIGS. 12A and 12B are diagrams illustrating an operation of a power supply device of FIG. 3.

FIG. 13 is a circuit diagram illustrating an example of a power supply device of FIG. 2.

FIG. 14 is a block diagram illustrating a power supply device according to some example embodiments.

FIGS. 15A and 15B are block diagrams illustrating examples of a control signal generating circuit included in a power supply device of FIG. 14.

FIGS. 16 and 17 are flowcharts illustrating a method of operating a power supply device according to some example embodiments.

FIG. 18 is a block diagram illustrating a memory module according to some example embodiments.

FIG. 19 is a block diagram illustrating an example of a memory device included in a memory module according to some example embodiments.

FIG. 20 is a block diagram illustrating an integrated circuit including a power supply device according to some example embodiments.

### DETAILED DESCRIPTION

Various example embodiments will be described more fully with reference to the accompanying drawings, in which some example embodiments are shown. The inventive concepts may, however, be embodied in many different forms and should not be construed as limited to the example embodiments set forth herein. Like reference numerals refer to like elements throughout this application.

When the terms “about” or “substantially” are used in this specification in connection with a numerical value, it is intended that the associated numerical value includes a manufacturing or operational tolerance (e.g., +10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes. When ranges are specified, the range includes all values therebetween such as increments of 0.1%.

Also, for example, “at least one of A, B, and C” and similar language (e.g., “at least one selected from the group consisting of A, B, and C”) may be construed as A only, B only, C only, or any combination of two or more of A, B, and C, such as, for instance, ABC, AB, BC, and AC.

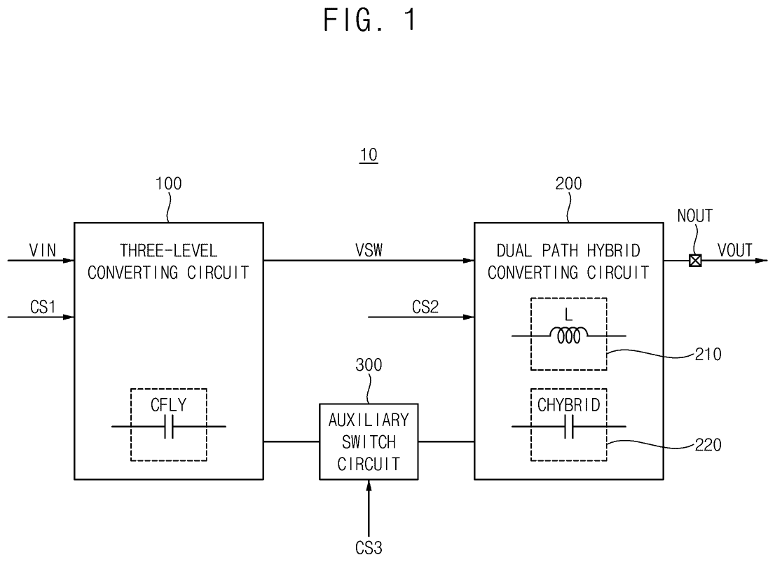

FIG. 1 is a block diagram illustrating a power supply device according to some example embodiments.

Referring to FIG. 1, a power supply device 10 includes a three-level converting circuit 100, a dual path hybrid converting circuit 200 and an auxiliary switch circuit 300.

The three-level converting circuit 100 includes a flying capacitor CFLY for a three-level operation. The three-level converting circuit 100 generates an intermediate voltage VSW by performing the three-level operation using an input voltage VIN, a plurality of first control signals CS1 and the flying capacitor CFLY.

A three-level operation (or three-level converting operation) may represent or indicate an operation where a voltage signal having a logic high level and a logic low level as well as a logic middle level (e.g., a voltage signal having three different voltage levels) is generated and/or converted. For example, the intermediate voltage VSW generated by the three-level converting circuit 100 may have three voltage levels that are different from one another. When the three-level operation is performed, an inductor alternating current (AC) current component (or term) of the power supply device 10 may be reduced.

The dual path hybrid converting circuit 200 includes a first path 210 and a second path 220 that are connected to an output node NOUT providing an output voltage VOUT and are different from each other. The first path 210 includes an inductor L, and the second path 220 includes a hybrid capacitor CHYBRID. For example, the dual path hybrid converting circuit 200 includes the inductor L that is disposed in the first path 210 and the hybrid capacitor CHYBRID that is disposed in the second path 220. The dual path hybrid converting circuit 200 generates the output voltage VOUT by performing a dual path operation using the intermediate voltage VSW, a second control signal CS2, the inductor L and the hybrid capacitor CHYBRID.

A dual path operation may represent an operation where an inductor current and a capacitor current are substantially simultaneously or concurrently formed or generated and are provided to an output terminal. For example, the output voltage VOUT generated by the dual path hybrid converting circuit 200 may be generated by substantially simultaneously driving the inductor L included in the first path 210 and the hybrid capacitor CHYBRID included in the second path 220. When the dual path operation is performed, an inductor direct current (DC) current component (or term) of the power supply device 10 may be reduced.

The auxiliary switch circuit 300 is disposed or arranged between the three-level converting circuit 100 and the dual path hybrid converting circuit 200. The auxiliary switch circuit 300 controls a current flow through the hybrid capacitor CHYBRID based on a third control signal CS3.

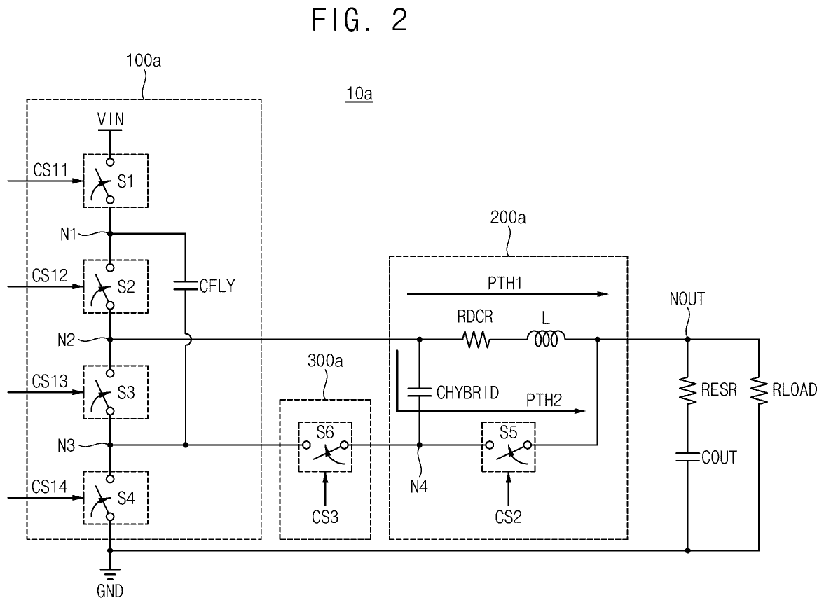

Examples of detailed circuit configurations of the three-level converting circuit 100, the dual path hybrid converting circuit 200 and the auxiliary switch circuit 300 will be described with reference to FIGS. 2, 3 and 13.

In some example embodiments, a voltage level of the output voltage VOUT that is generated by the power supply device 10 may be lower than a voltage level of the input voltage VIN that is received by the power supply device 10. For example, the power supply device 10 may be or may have a configuration corresponding to a buck converter or a stepdown converter that converts a relatively high DC voltage into a relatively low DC voltage.

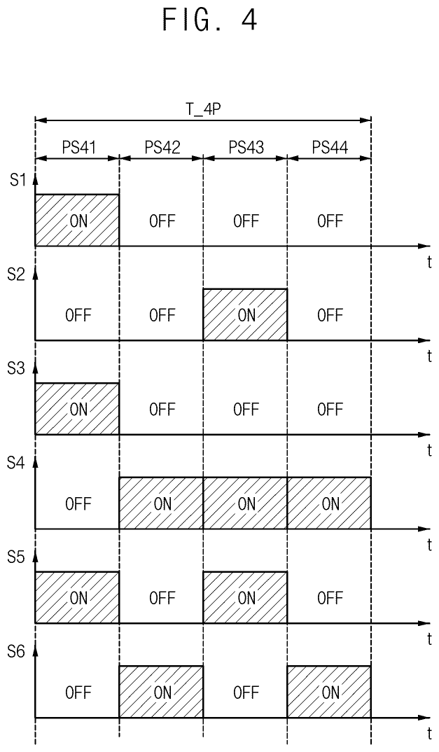

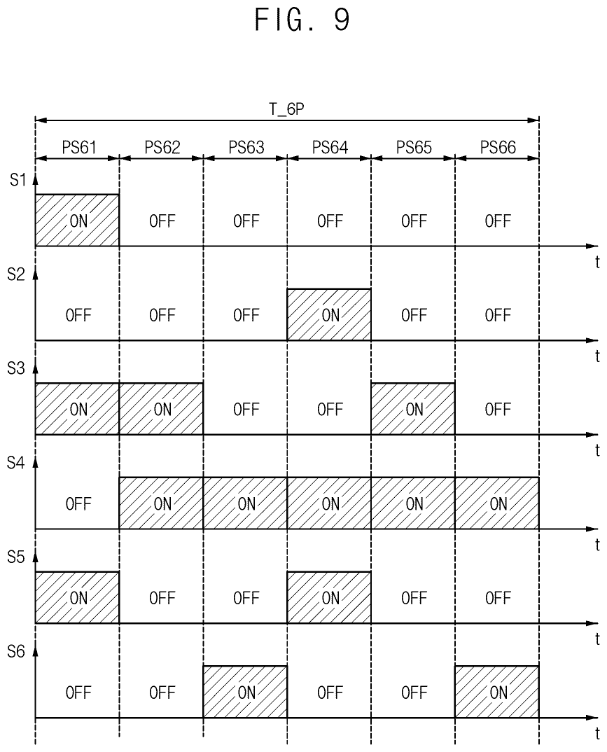

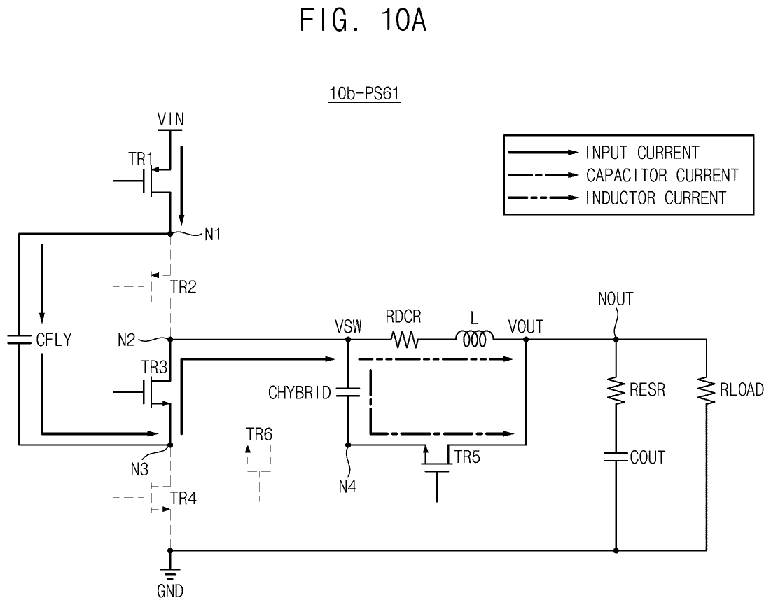

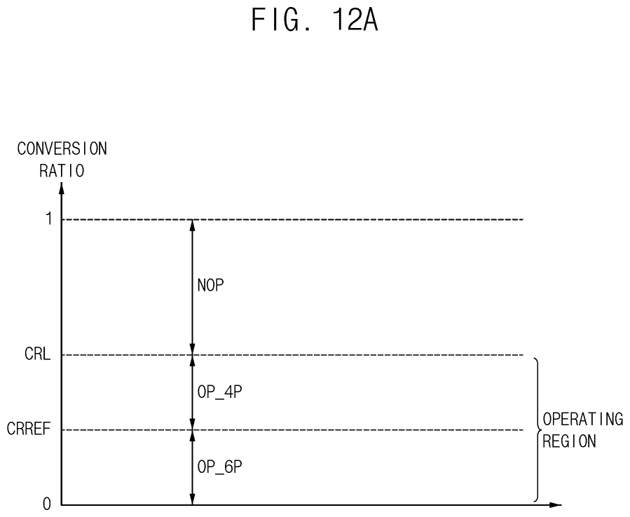

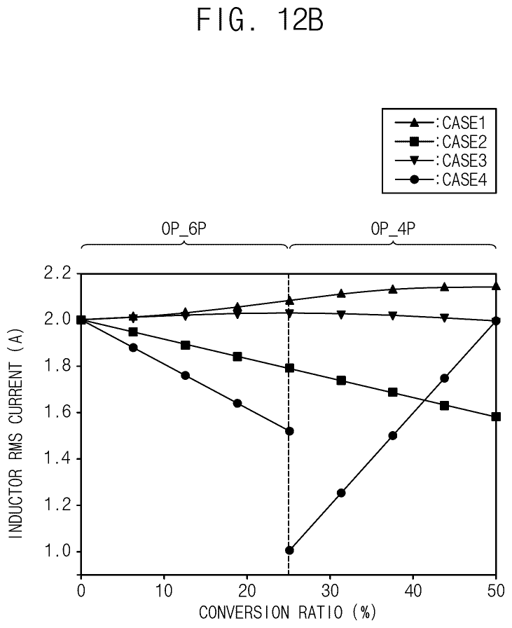

In some example embodiments, the power supply device 10 may operate based on a four-phase scheme (or method) or a six-phase scheme depending on an operation mode. For example, the operation mode may be determined based on a conversion ratio obtained by dividing the output voltage VOUT by the input voltage VIN. The four-phase scheme will be described with reference to FIGS. 4, 5A, 5B, 5C, 5D, 6A and 6B. The six-phase scheme will be described with reference to FIGS. 9, 10A, 10B, 10C, 10D, 10E, 10F, 11A and 11B. The operation of determining the operation mode will be described with reference to FIGS. 12A and 12B.

A power supply device is widely used in various electronic devices and is implemented with an inductor. To reduce loss due to a DC resistance (DCR) of the inductor, an inductor with a relatively large physical size has been used. Various research has been undertaken to reduce the physical size of the inductor, however, there were problems that the DC resistance of the inductor increases and a conversion efficiency of the power supply device decreases when the physical size of the inductor is reduced.

The power supply device 10 according to some example embodiments may include the flying capacitor CFLY for the three-level operation, as well as the inductor L and the hybrid capacitor CHYBRID for the dual path operation. For example, the power supply device 10 may be implemented in the form of a three-level dual path hybrid buck converter. The AC current component may be reduced by the three-level operation, and the DC current component may be reduced by the dual path operation. Accordingly, even in an environment where the physical size of the inductor is relatively small and the DC resistance of the inductor is relatively large, the loss due to the DC resistance may be reduced by reducing a root mean square (RMS) current of the inductor, and thus a decrease in the conversion efficiency may be limit and/or prevented.

FIG. 2 is a circuit diagram illustrating a power supply device according to some example embodiments.

Referring to FIG. 2, a power supply device 10a includes a three-level converting circuit 100a, a dual path hybrid converting circuit 200a and an auxiliary switch circuit 300a.

The three-level converting circuit 100a may include a first switch S1, a second switch S2, a third switch S3, a fourth switch S4 and the flying capacitor CFLY.

The first switch S1 may be connected between the input voltage VIN and a first node N1, and may be turned on and off in response to a control signal CS11. The second switch S2 may be connected between the first node N1 and a second node N2, and may be turned on and off in response to a control signal CS12. The third switch S3 may be connected between the second node N2 and a third node N3, and may be turned on and off in response to a control signal CS13. The fourth switch S4 may be connected between the third node N3 and a ground voltage GND, and may be turned on and off in response to a control signal CS14. The flying capacitor CFLY may be connected between the first node N1 and the third node N3, and may be charged and discharged by operations of the switches S1, S2, S3 and S4. The control signals CS11, CS12, CS13 and CS14 may correspond to the plurality of first control signals CS1 in FIG. 1.

The dual path hybrid converting circuit 200a may include a fifth switch S5, the inductor L and the hybrid capacitor CHYBRID.

The fifth switch S5 may be connected between the fourth node N4 and the output node NOUT, and may be turned on and off in response to the second control signal CS2. The inductor L may be connected between the second node N2 and the output node NOUT. A resistor RDCR may be a DC resistance of the inductor L, and may represent a parasitic component rather than an actual element. The hybrid capacitor CHYBRID may be connected between the second node N2 and the fourth node N4.

A first path PTH1 may represent a path between the second node N2 and the output node NOUT, and may include the inductor L. A second path PTH2 may represent a path between the second node N2 and the output node NOUT, and may include the hybrid capacitor CHYBRID and the fifth switch S5.

The auxiliary switch circuit 300a may include a sixth switch S6. The sixth switch S6 may be connected between the third node N3 and the fourth node N4, and may be turned on and off in response to the third control signal CS3.

The power supply device 10a may further include an output capacitor COUT that is connected between the output node NOUT and the ground voltage GND. A resistor RESR may be an equivalent series resistance (ESR) of the output capacitor COUT, and may represent a parasitic component rather than an actual element.

A load resistor RLOAD may not be a component of the power supply device 10a, and may represent a resistance of an external device that is connected to the power supply device 10a and receives power (e.g., the output voltage VOUT) from the power supply device 10a.

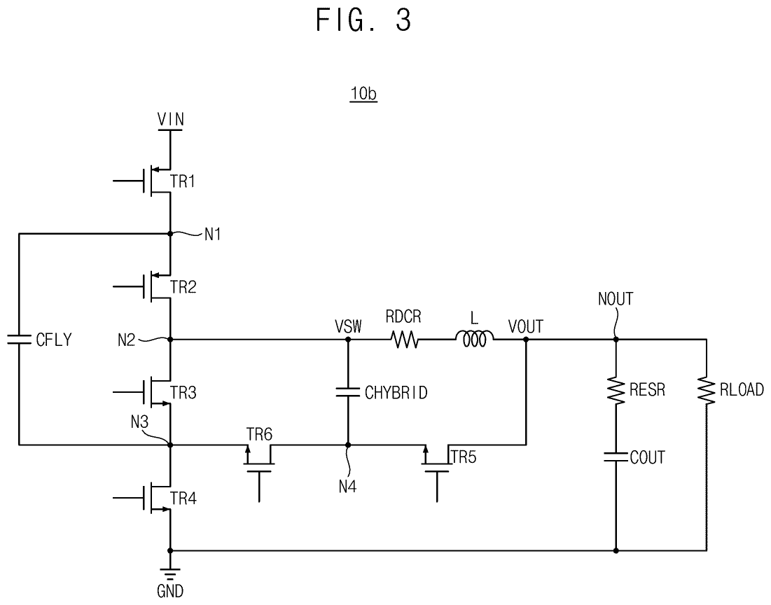

FIG. 3 is a circuit diagram illustrating an example of a power supply device of FIG. 2. The descriptions repeating or overlapping with descriptions of FIG. 2 will be omitted in the interest of brevity.

Referring to FIG. 3, a power supply device 10b may include a first transistor TR1, a second transistor TR2, a third transistor TR3, a fourth transistor TR4, a fifth transistor TR5, a sixth transistor TR6, the flying capacitor CFLY, the inductor L, the hybrid capacitor CHYBRID and the output capacitor COUT.

The first transistor TR1 may be connected between the input voltage VIN and the first node N1, the second transistor TR2 may be connected between the first node N1 and the second node N2, the third transistor TR3 may be connected between the second node N2 and the third node N3, and the fourth transistor TR4 may be connected between the third node N3 and the ground voltage GND. The first, second, third and fourth transistors TR1, TR2, TR3 and TR4 may correspond to the first, second, third and fourth switches S1, S2, S3 and S4 in FIG. 2, respectively, and the control signals CS11, CS12, CS13 and CS14 in FIG. 2 may be applied to gate electrodes of the first, second, third and fourth transistors TR1, TR2, TR3 and TR4, respectively.

The fifth transistor TR5 may be connected between the fourth node N4 and the output node NOUT. The fifth transistor TR5 may correspond to the fifth switch S5 in FIG. 2, and the second control signal CS2 in FIG. 2 may be applied to a gate electrode of the fifth transistor TR5.

The sixth transistor TR6 may be connected between the third node N3 and the fourth node N4, and may be implemented such that a body bias voltage of the sixth transistor TR6 is changeable or variable (e.g., such that a body selection is possibly performed on the sixth transistor TR6). The sixth transistor TR6 may correspond to the sixth switch S6 in FIG. 2, and the third control signal CS3 in FIG. 2 may be applied to a gate electrode of the sixth transistor TR6.

In some example embodiments, the first and second transistors TR1 and TR2 may be p-type metal oxide semiconductor (PMOS) transistors, and the third, fourth, fifth and sixth transistors TR3, TR4, TR5 and TR6 may be n-type metal oxide semiconductor (NMOS) transistors. However, some example embodiments are not limited thereto. For example, the first and second transistors TR1 and TR2 may be NMOS transistors. For example, the first and second transistors TR1 and TR2 may be implemented with one of PMOS transistors and NMOS transistors.

As described above, the resistors RDCR and RESR may represent the parasitic components rather than the actual elements, and the load resistor RLOAD may represent the resistance of the external device. Therefore, the power supply device 10b may include six transistors TR1, TR2, TR3, TR4, TR5 and TR6, three capacitors CFLY, CHYBRID and COUT, and one inductor L.

FIGS. 4, 5A, 5B, 5C, 5D, 6A and 6B are diagrams illustrating an operation of a power supply device of FIG. 3.

Referring to FIG. 4, the power supply device 10b may operate based on the four-phase scheme, and may perform repetitive operations every desired and/or predetermined operation cycle (or switching cycle) T_4P.

For example, the operation cycle T_4P of the four-phase scheme may include a first phase (or state) PS41, a second phase PS42, a third phase PS43 and a fourth phase PS44.

In the first phase PS41, the first, third and fifth switches S1, S3 and S5 (e.g., the first, third and fifth transistors TR1, TR3 and TR5) may be turned on (e.g., closed), and the second, fourth and sixth switches S2, S4 and S6 (e.g., the second, fourth and sixth transistors TR2, TR4 and TR6) may be turned off (e.g., opened).

In the second phase PS42, the fourth and sixth switches S4 and S6 (e.g., the fourth and sixth transistors TR4 and TR6) may be turned on, and the first, second, third and fifth switches S1, S2, S3 and S5 (e.g., the first, second, third and fifth transistors TR1, TR2, TR3 and TR5) may be turned off.

In the third phase PS43, the second, fourth and fifth switches S2, S4 and S5 (e.g., the second, fourth and fifth transistors TR2, TR4 and TR5) may be turned on, and the first, third and sixth switches S1, S3 and S6 (e.g., the first, third and sixth transistors TR1, TR3 and TR6) may be turned off.

In the fourth phase PS44, as with the second phase PS42, the fourth and sixth switches S4 and S6 (e.g., the fourth and sixth transistors TR4 and TR6) may be turned on, and the first, second, third and fifth switches S1, S2, S3 and S5 (e.g., the first, second, third and fifth transistors TR1, TR2, TR3 and TR5) may be turned off.

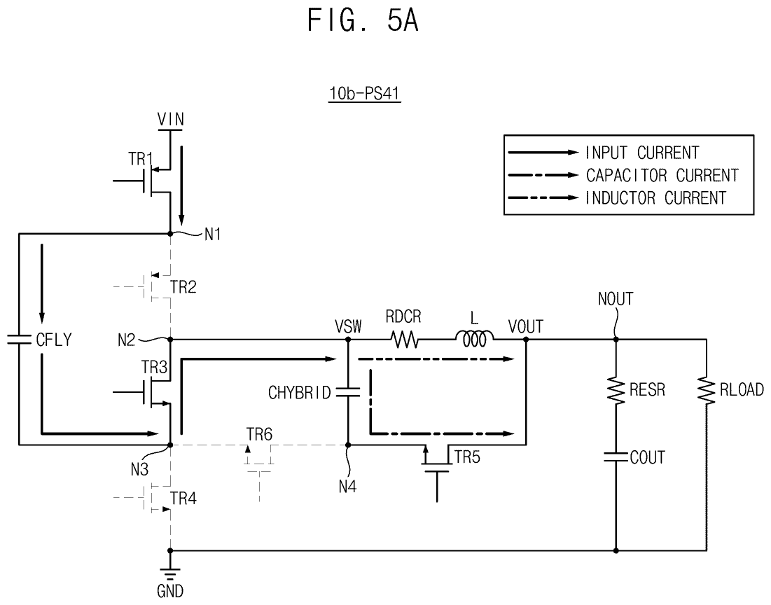

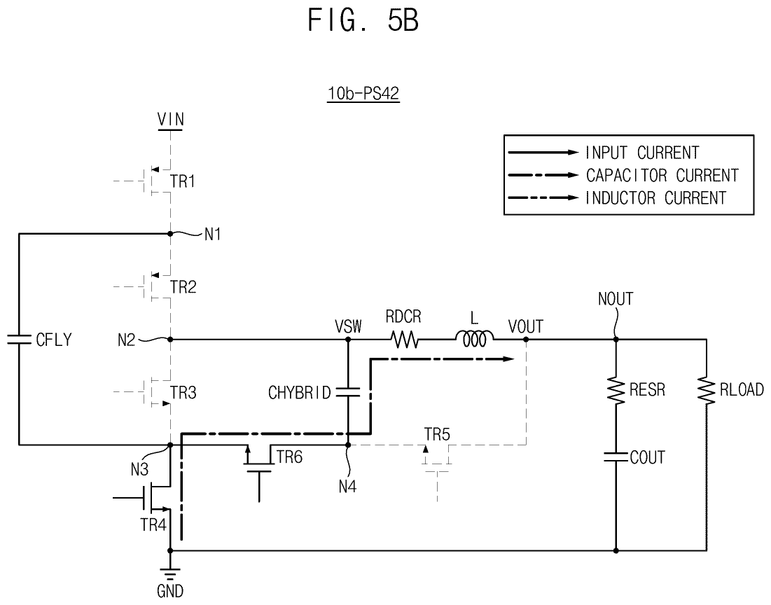

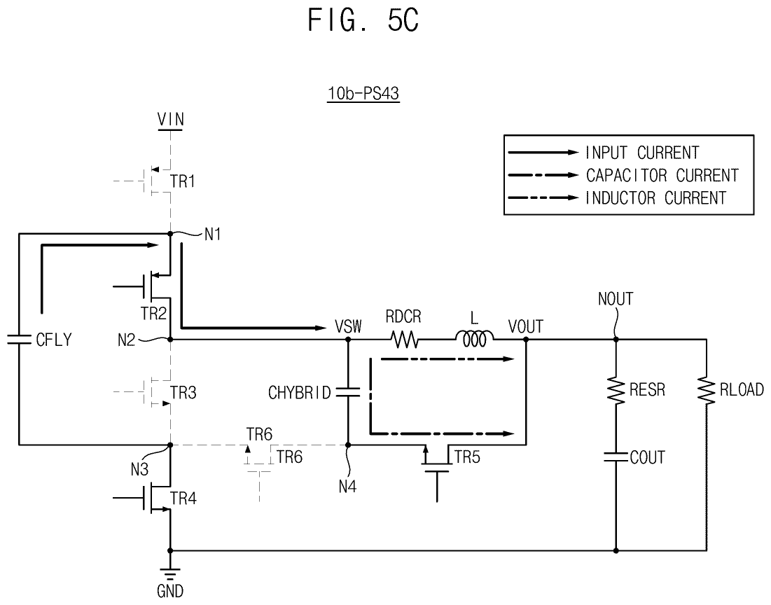

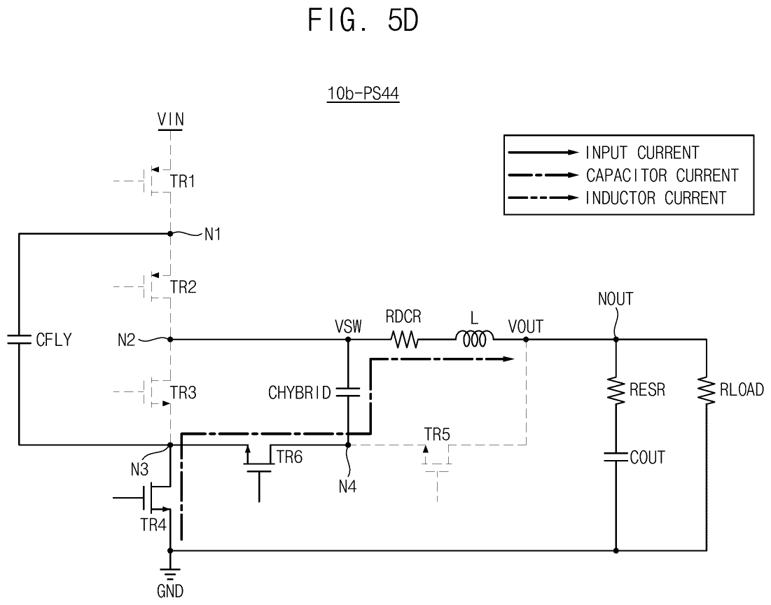

Referring to FIG. 5A, a connection state 10b_PS41 of the components included in the power supply device 10b is illustrated with respect to the first phase PS41, and an operation related thereto is illustrated.

As described with reference to FIG. 4, in the first phase PS41, the first and third transistors TR1 and TR3 may be turned on, and the flying capacitor CFLY may be charged based on the input voltage VIN. An input current provided by the input voltage VIN may flow to the second node N2 through the first transistor TR1, the flying capacitor CFLY and the third transistor TR3. The intermediate voltage VSW may be formed by the input current.

An inductor current may flow to the output node NOUT through the inductor L included in the first path (e.g., the first path PTH1 in FIG. 2) between the second node N2 and the output node NOUT. In the first phase PS41, the fifth transistor TR5 may be turned on, the second path (e.g., the second path PTH2 in FIG. 2) between the second node N2 and the output node NOUT may be electrically connected to the output node NOUT, and thus a capacitor current may flow to the output node NOUT through the hybrid capacitor CHYBRID included in the second path PTH2. The output voltage VOUT may be formed by the inductor current and the capacitor current.

Referring to FIG. 5B, a connection state 10b_PS42 of the components included in the power supply device 10b is illustrated with respect to the second phase PS42, and an operation related thereto is illustrated.

As described with reference to FIG. 4, in the second phase PS42, the fourth and sixth transistors TR4 and TR6 may be turned on, and a capacitor current may flow to the output node NOUT through the hybrid capacitor CHYBRID. For example, to limit and/or prevent the capacitor current from unintentionally leaking toward the ground voltage GND, the body bias voltage of the sixth transistor TR6 may be controlled or adjusted (e.g., the body selection may be performed on the sixth transistor TR6). The fifth transistor TR5 may be turned off, and thus the capacitor current may flow to the output node NOUT through the inductor L. The intermediate voltage VSW and the output voltage VOUT may be formed by the capacitor current.

Referring to FIG. 5C, a connection state 10b_PS43 of the components included in the power supply device 10b is illustrated with respect to the third phase PS43, and an operation related thereto is illustrated.

As described with reference to FIG. 4, in the third phase PS43, the second and fourth transistors TR2 and TR4 may be turned on, and the flying capacitor CFLY charged in the first phase PS41 may be discharged. An input current provided from the flying capacitor CFLY charged by the input voltage VIN may flow to the second node N2 through the second transistor TR2. The intermediate voltage VSW may be formed by the input current.

An inductor current may flow to the output node NOUT through the inductor L included in the first path PTH1. In the third phase PS43, the fifth transistor TR5 may be turned on, and a capacitor current may flow to the output node NOUT through the hybrid capacitor CHYBRID included in the second path PTH2. The output voltage VOUT may be formed by the inductor current and the capacitor current.

Referring to FIG. 5D, a connection state 10b_PS44 of the components included in the power supply device 10b is illustrated with respect to the fourth phase PS44, and an operation related thereto is illustrated.

An operation in the fourth phase PS44 may be similar to the operation in the second phase PS42. For example, as described with reference to FIG. 4, in the fourth phase PS44, the fourth and sixth transistors TR4 and TR6 may be turned on, and a capacitor current may flow to the output node NOUT through the hybrid capacitor CHYBRID. The intermediate voltage VSW and the output voltage VOUT may be formed by the capacitor current.

For example, in the first phase PS41 and the third phase PS43 illustrated in FIGS. 5A and 5C, the output voltage VOUT may be generated based on the inductor current of the inductor L and the capacitor current of the hybrid capacitor CHYBRID that are obtained by the dual path operation. In the second phase PS42 and the fourth phase PS44 illustrated in FIGS. 5B and 5D, the output voltage VOUT may be generated based on the capacitor current of the hybrid capacitor CHYBRID. For example, the inductor current and the capacitor current in the first phase PS41 may be collectively referred to as a first current, the capacitor current in the second phase PS42 may be referred to as a second current, the inductor current and the capacitor current in the third phase PS43 may be collectively referred to as a third current, and the capacitor current in the fourth phase PS44 may be referred to as a fourth current.

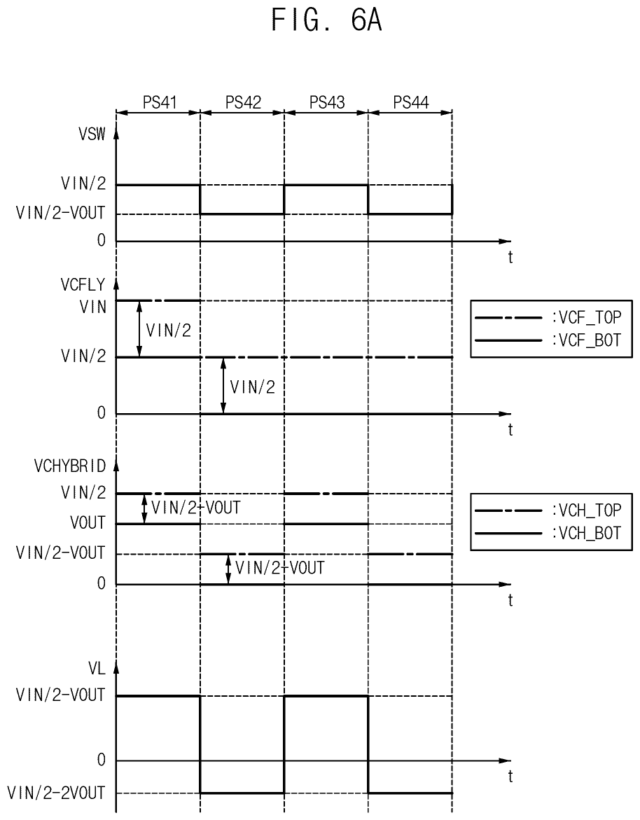

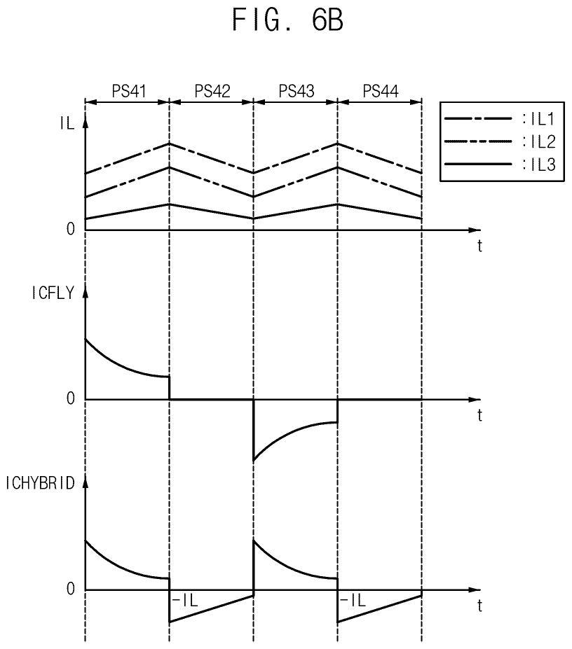

Referring to FIG. 6A, changes in the intermediate voltage VSW, a voltage VCFLY of the flying capacitor CFLY, a voltage VCHYBRID of the hybrid capacitor CHYBRID and a voltage VL of the inductor L are illustrated in the first, second, third and fourth phases PS41, PS42, PS43 and PS44. The voltage VCFLY of the flying capacitor CFLY, the voltage VCHYBRID of the hybrid capacitor CHYBRID and the voltage VL of the inductor L may be referred to as a flying capacitor voltage, a hybrid capacitor voltage and an inductor voltage, respectively.

The voltage VCFLY of the flying capacitor CFLY may vary or may be changed as illustrated in FIG. 6A, depending on whether the flying capacitor CFLY is connected or not to the input voltage VIN.

For example, in the first phase P41, a voltage level of a voltage VCF_TOP at a first electrode (e.g., an upper electrode) of the flying capacitor CFLY that is connected to the first node N1 may be substantially equal to a voltage level of the input voltage VIN, and a voltage level of a voltage VCF_BOT at a second electrode (e.g., a lower electrode) of the flying capacitor CFLY that is connected to the third node N3 may be substantially equal to a half (e.g., VIN/2) of the voltage level of the input voltage VIN. In the second, third and fourth phases PS42, PS43 and PS44, the voltage level of the voltage VCF_TOP at the first electrode of the flying capacitor CFLY may be substantially equal to a half (e.g., VIN/2) of the voltage level of the input voltage VIN, and the voltage level of the voltage VCF_BOT at the second electrode of the flying capacitor CFLY may be substantially equal to a voltage level (e.g., about 0V) of the ground voltage GND. Therefore, in all of the first, second, third and fourth phases PS41, PS42, PS43 and PS44, a difference in the voltage levels between the first and second electrodes of the flying capacitor CFLY may be maintained to about VIN/2.

The intermediate voltage VSW may vary or may be changed as illustrated in FIG. 6A, depending on whether the input current is supplied or not.

For example, in the first and third phases PS41 and PS43, a voltage level of the intermediate voltage VSW may be substantially equal to a half (e.g., VIN/2) of the voltage level of the input voltage VIN. In the second and fourth phases PS42 and PS44, the voltage level of the intermediate voltage VSW may be substantially equal to a difference (e.g., VIN/2−VOUT) between a half of the voltage level of the input voltage VIN and a voltage level of the output voltage VOUT. By performing the three-level operation, the intermediate voltage VSW may have three different voltage levels, e.g., the voltage level (e.g. VIN/2) corresponding to the logic high level, the voltage level (e.g. about 0V) corresponding to the logic low level, and the voltage level (e.g. VIN/2-VOUT) corresponding to the logic middle level.

The voltage VCHYBRID of the hybrid capacitor CHYBRID and the voltage VL of the inductor L may vary or may be changed as illustrated in FIG. 6A, based on the intermediate voltage VSW.

For example, in the first and third phases PS41 and PS43, a voltage level of a voltage VCH_TOP at a first electrode (e.g., an upper electrode) of the hybrid capacitor CHYBRID that is connected to the second node N2 may be substantially equal to a half (e.g., VIN/2) of the voltage level of the input voltage VIN, and a voltage level of a voltage VCH_BOT at a second electrode (e.g., a lower electrode) of the hybrid capacitor CHYBRID that is connected to the fourth node N4 may be substantially equal to the voltage level of the output voltage VOUT. In the second and fourth phases PS42 and PS44, the voltage level of the voltage VCH_TOP at the first electrode of the hybrid capacitor CHYBRID may be substantially equal to a difference (e.g., VIN/2-VOUT) between a half of the voltage level of the input voltage VIN and the voltage level of the output voltage VOUT, and the voltage level of the voltage VCH_BOT at the second electrode of the hybrid capacitor CHYBRID may be substantially equal to the voltage level (e.g., about 0V) of the ground voltage GND. Therefore, in all of the first, second, third and fourth phases PS41, PS42, PS43 and PS44, a difference in the voltage levels between the first and second electrodes of the hybrid capacitor CHYBRID may be maintained to about VIN/2-VOUT.

For example, in the first and third phases PS41 and PS43, a voltage level of the voltage VL of the inductor L may be substantially equal to a difference (e.g., VIN/2−VOUT) between a half of the voltage level of the input voltage VIN and the voltage level of the output voltage VOUT. In the second and fourth phases PS42 and PS44, the voltage level of the voltage VL of the inductor L may be substantially equal to a difference (e.g. VIN/2−2*VOUT) between a half of the voltage level of the input voltage VIN and twice the voltage level of the output voltage VOUT.

In some example embodiments, based on the above-described changes in the voltages VSW, VCFLY and VCHYBRID and a voltage-second balance condition of the inductor L, a duty ratio D of the inductor L may be obtained by Equation 1, Equation 2 and Equation 3.

$$( \frac{VIN}{2} - VOUT ) * D * T = ( 2 * VOUT - \frac{VIN}{2} ) * ( 1 - D ) * T \qquad [ Equation 1 ]$$

$$\frac{VIN}{2} = ( 2 - D ) * VOUT \qquad [ Equation 2 ]$$

$$D = \frac{4 * VOUT - VIN}{2 * VOUT} \qquad [ Equation 3 ]$$

The duty ratio D may represent a ratio of a time interval during which the voltage VL of the inductor L has the logic high level (e.g., the voltage level VIN/2−VOUT) for the total time interval and T may represent the entire operation cycle. For example, the duty ratio D may represent a ratio of time intervals corresponding to the first and third phases PS41 and PS43 for the entire operation cycle T_4P. Time intervals corresponding to the first, second, third and fourth phases PS41, PS42, PS43 and PS44 may be determined based on the duty ratio D.

In some example embodiments, a relationship between a current IL of the inductor L, a capacitor current IC and an output current IOUT may be obtained by Equation 4. For example, D′=1-D in Equation 4. Based on a capacitor charge balance condition, a relationship between the current IL of the inductor L and the capacitor current IC may be obtained by Equation 5 and Equation 6. Based on Equation 4, Equation 5 and Equation 6, the current IL of the inductor L may be obtained by Equation 7.

$$D * \{ IL + IC \} + {D}^{′} * IL = IOUT \qquad [ Equation 4 ]$$

$${D}^{′} * IL = D * IC \qquad [ Equation 5 ]$$

$$IL = \frac{D}{{D}^{′}} * IC \to IC = \frac{{D}^{′}}{D} * IL \qquad [ Equation 6 ]$$

$$IL = \frac{IOUT}{( 2 - D )} \qquad [ Equation 7 ]$$

Referring to FIG. 6B, changes in the current IL of the inductor L, a current ICFLY of the flying capacitor CFLY and a current ICHYBRID of the hybrid capacitor CHYBRID are illustrated in the first, second, third and fourth phases PS41, PS42, PS43 and PS44. The current ICFLY of the flying capacitor CFLY and the current ICHYBRID of the hybrid capacitor CHYBRID may be referred to as a flying capacitor current and a hybrid capacitor current, respectively.

In the current IL of the inductor L in FIG. 6B, ‘IL1’ may represent a case of a conventional buck converter that performs neither the three-level operation nor the dual path operation, ‘IL2’ may represent a case of a buck converter that performs only the dual path operation, and ‘IL3’ may represent a case of a buck converter according to example some example embodiments that performs both the three-level operation and the dual path operation. In ‘IL3’, it can be seen that the DC component decreases because an average value of the current is relatively low and the AC component decreases because variation, fluctuation and/or ripple in the current are relatively small, as compared with ‘IL1’ and ‘IL2’. Accordingly, the conduction loss may be reduced in the buck converter according to some example embodiments.

The current ICFLY of the flying capacitor CFLY and the current ICHYBRID of the hybrid capacitor CHYBRID may vary or may be changed as illustrated in FIG. 6B. The capacitor charge balance condition may be satisfied for the current ICHYBRID of the hybrid capacitor CHYBRID.

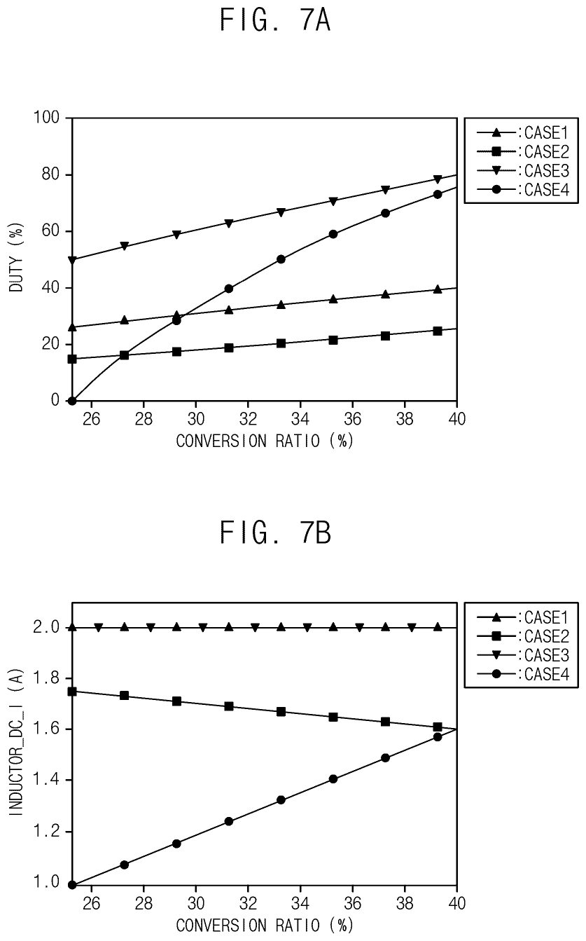

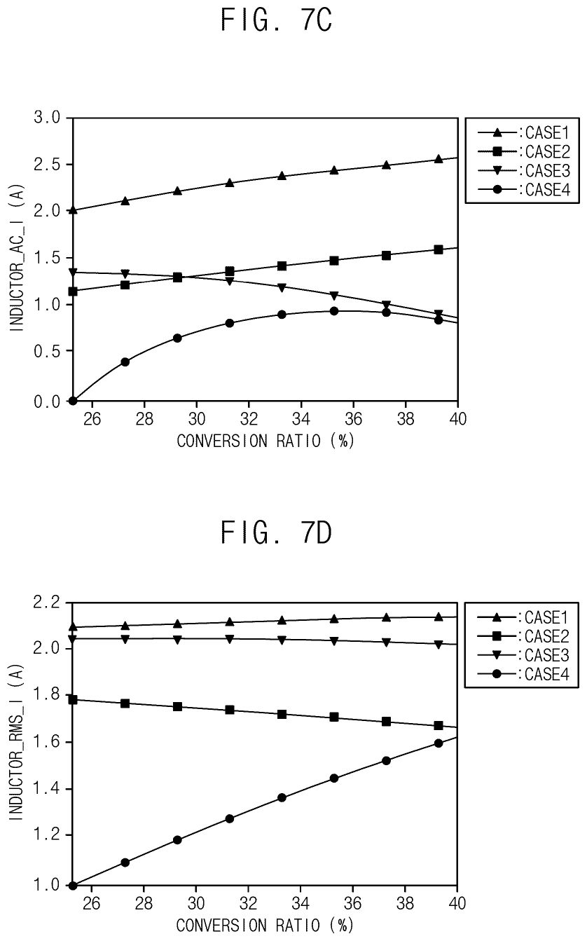

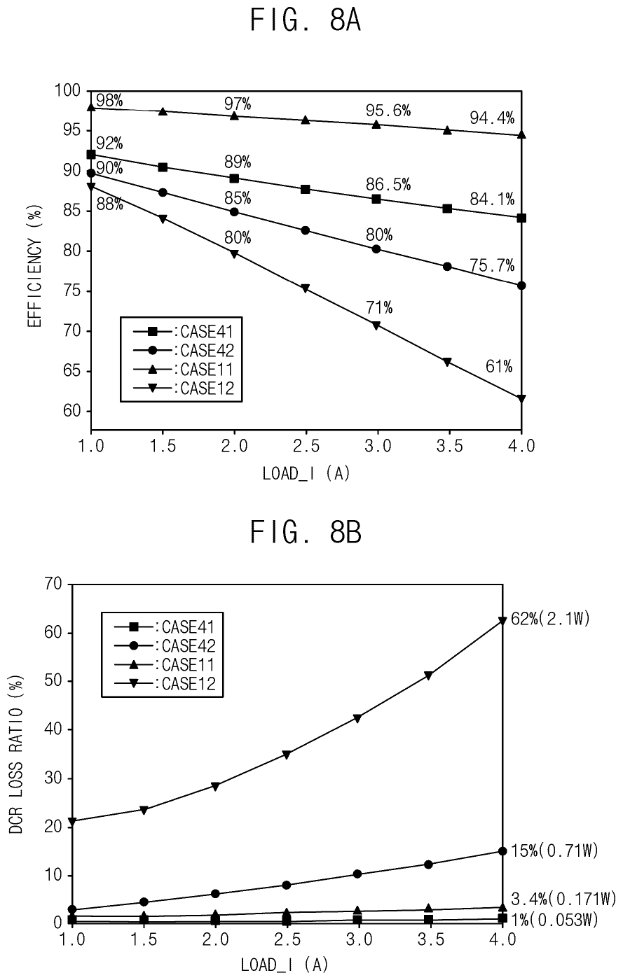

FIGS. 7A, 7B, 7C, 7D, 8A and 8B are diagrams illustrating performance of a power supply device of FIG. 3.

Referring to FIGS. 7A, 7B, 7C and 7D, a duty ratio, an inductor DC current INDUCTOR_DC_I, an inductor AC current INDUCTOR_AC_I and an inductor RMS current INDUCTOR_RMS_I of four different types of converters are illustrated depending on a conversion ratio of four different types of converters.

In FIGS. 7A, 7B, 7C and 7D, ‘CASE1’ may represent a case of a conventional buck converter that performs neither the three-level operation nor the dual path operation, ‘CASE2’ may represent a case of a buck converter that only performs the dual path operation, ‘CASE3’ may represent a case of a buck converter that only performs the three-level operation, and ‘CASE4’ may represent a case of a buck converter according to some example embodiments that performs both the three-level operation and the dual path operation. FIGS. 7A, 7B, 7C and 7D illustrate examples where the input voltage VIN, the output voltage VOUT and a switching frequency are the same as with respect to all converters and a load current is about 2 A with respect to all converters.

In ‘CASE4’, it can be seen that the inductor current decreases in a section where the conversion ratio (=VOUT/VIN) is from about 25% to about 40%, as compared with ‘CASE1’, ‘CASE2’ and ‘CASE3’. For example, with respect to the inductor RMS current INDUCTOR_RMS_I illustrated in FIG. 7D, the inductor RMS current may be reduced by up to about 51% in ‘CASE4’ as compared with ‘CASE1’, and the inductor RMS current may be reduced by up to about 44% in ‘CASE4’ as compared with ‘CASE2’.

Referring to FIGS. 8A and 8B, a converter efficiency and loss ratio due to DC resistance of two different types of converters are illustrated depending on a load current LOAD_I of two different types of converters.

In FIGS. 8A and 8B, ‘CASE41’ may represent a case where the DC resistance is about 10 mΩ in a buck converter according to some example embodiments that performs both the three-level operation and the dual path operation, ‘CASE42’ may represent a case where the DC resistance is about 120 mΩ in a buck converter according to some example embodiments that performs both the three-level operation and the dual path operation, ‘CASE11’ may represent a case where the DC resistance is about 10 mΩ in a conventional buck converter that performs neither the three-level operation nor the dual path operation, and ‘CASE12’ may represent a case where the DC resistance is about 120 m (2 in a conventional buck converter that performs neither the three-level operation nor the dual path operation. FIGS. 8A and 8B illustrate examples where the input voltage VIN and the switching frequency are the same as with respect to all converters and the output voltage VOUT is about 1.35V with respect to all converters.

As illustrated in FIG. 8A, it can be seen that the conventional buck converter has a relatively large decrease in the converter efficiency due to an increase in the DC resistance and the buck converter according to some example embodiments has a relatively small decrease in the converter efficiency due to an increase in the DC resistance. For example, as illustrated by ‘CASE11’ and ‘CASE12’, when the load current LOAD_I is about 4 A and the DC resistance increases from about 10 mΩ to about 120 mΩ in the conventional buck converter, the converter efficiency may decrease by about 33.4%. In contrast, as illustrated by ‘CASE41’ and ‘CASE42’, when the load current LOAD_I is about 4 A and the DC resistance increases from about 10 msΩ to about 120 mΩ in the buck converter according to some example embodiments, the converter efficiency may decrease by about 8.4%.

As illustrated in FIG. 8B, in the buck converter according to some example embodiments of ‘CASE41’ and ‘CASE42’, it can be seen that the loss due to the DC resistance is relatively small, as compared with the conventional buck converter of ‘CASE11’ and ‘CASE12’.

As described above, the power supply device according to some example embodiments that performs both the three-level operation and the dual path operation may have a structure that can reduce (and/or minimize) the loss due to the DC resistance of the inductor. Accordingly, when the power supply device according to some example embodiments that performs both the three-level operation and the dual path operation is applied, employed or adopted, a relatively small inductor may be used in the power supply device, and the reduction in circuit size and the improvement in power integrity (PI) may be achieved. Further, an additional space that is obtained by reducing a physical size of the inductor may be utilized to increase a physical size of the capacitor.

FIGS. 9, 10A, 10B, 10C, 10D, 10E, 10F, 11A and 11B are diagrams illustrating an operation of a power supply device of FIG. 3. The descriptions repeating or overlapping with descriptions of FIGS. 4, 5A, 5B, 5C, 5D, 6A and 6B will be omitted in the interest of brevity.

Referring to FIG. 9, the power supply device 10b may operate based on the six-phase scheme, and may perform repetitive operations every desired and/or predetermined operation cycle T_6P.

For example, the operation cycle T_6P of the six-phase scheme may include a first phase PS61, a second phase PS62, a third phase PS63, a fourth phase PS64, a fifth phase PS65 and a sixth phase P66.

In the first phase PS61, the first, third and fifth switches S1, S3 and S5 (e.g., the first, third and fifth transistors TR1, TR3 and TR5) may be turned on, and the second, fourth and sixth switches S2, S4 and S6 (e.g., the second, fourth and sixth transistors TR2, TR4 and TR6) may be turned off.

In the second phase PS62, the third and fourth switches S3 and S4 (e.g., the third and fourth transistors TR3 and TR4) may be turned on, and the first, second, fifth and sixth switches S1, S2, S5 and S6 (e.g., the first, second, fifth and sixth transistors TR1, TR2, TR5 and TR6) may be turned off.

In the third phase PS63, the fourth and sixth switches S4 and S6 (e.g., the fourth and sixth transistors TR4 and TR6) may be turned on, and the first, second, third and fifth switches S1, S2, S3 and S5 (e.g., the first, second, third and fifth transistors TR1, TR2, TR3 and TR5) may be turned off.

In the fourth phase PS64, the second, fourth and fifth switches S2, S4 and S5 (e.g., the second, fourth and fifth transistors TR2, TR4 and TR5) may be turned on, and the first, third and sixth switches S1, S3 and S6 (e.g., the first, third and sixth transistors TR1, TR3 and TR6) may be turned off.

In the fifth phase P65, the third and fourth switches S3 and S4 (e.g., the third and fourth transistors TR3 and TR4) may be turned on, and the first, second, fifth and sixth switches S1, S2, S5 and S6 (e.g., the first, second, fifth and sixth transistors TR1, TR2, TR5 and TR6) may be turned off.

In the sixth phase PS66, the fourth and sixth switches S4 and S6 (e.g., the fourth and sixth transistors TR4 and TR6) may be turned on, and the first, second, third and fifth switches S1, S2, S3 and S5 (e.g., the first, second, third and fifth transistors TR1, TR2, TR3 and TR5) may be turned off.

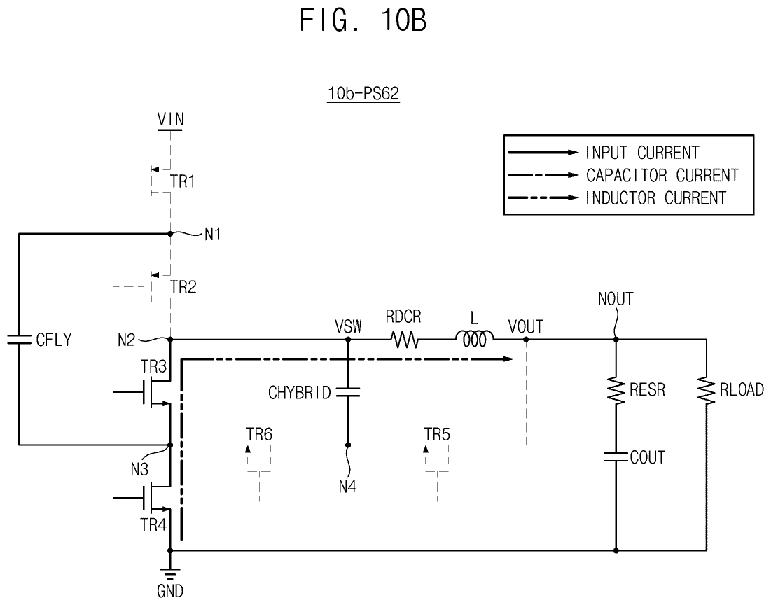

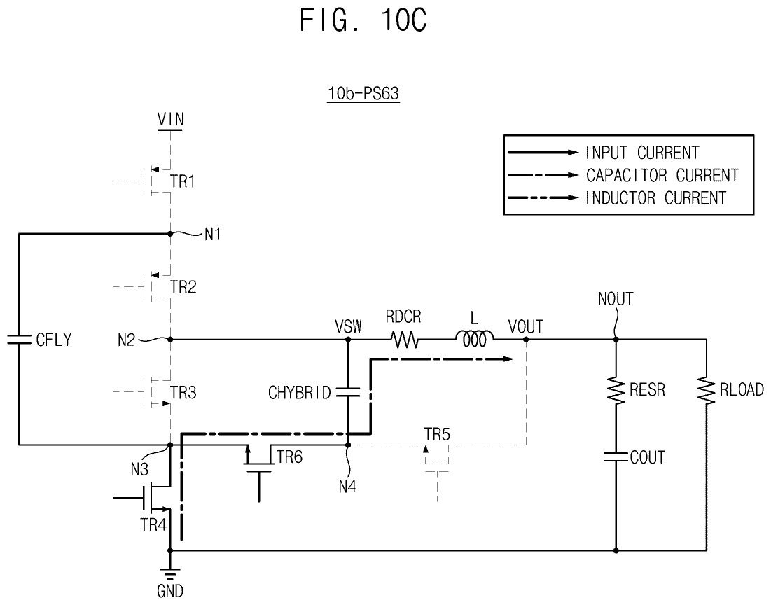

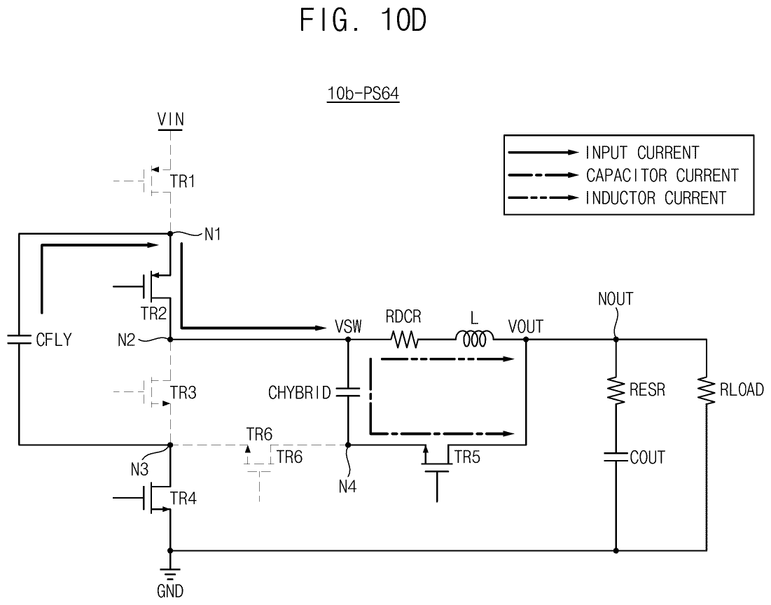

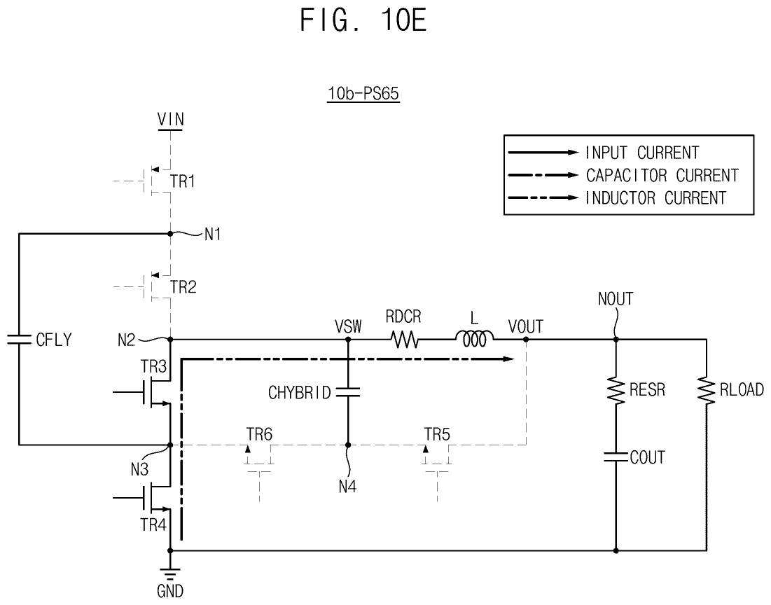

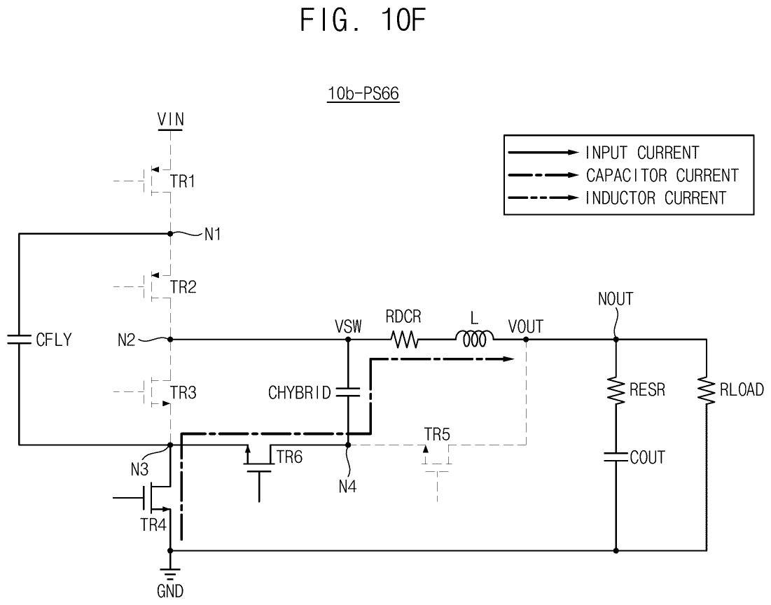

Referring to FIG. 10A, a connection state 10b_PS61 of the components included in the power supply device 10b is illustrated with respect to the first phase PS61, and an operation related thereto is illustrated. FIG. 10A may be substantially the same as that described with reference to FIG. 5A.

Referring to FIG. 10B, a connection state 10b_PS62 of the components included in the power supply device 10b is illustrated with respect to the second phase PS62, and an operation related thereto is illustrated.

As described with reference to FIG. 9, in the second phase PS62, the third and fourth transistors TR3 and TR4 may be turned on, and an inductor current may flow to the output node NOUT through the inductor L. The intermediate voltage VSW and the output voltage VOUT may be formed by the inductor current.

Referring to FIG. 10C, a connection state 10b_PS63 of the components included in the power supply device 10b is illustrated with respect to the third phase PS63, and an operation related thereto is illustrated. FIG. 10C may be substantially the same as that described with reference to FIG. 5B.

Referring to FIG. 10D, a connection state 10b_PS64 of the components included in the power supply device 10b is illustrated with respect to the fourth phase PS64, and an operation related thereto is illustrated. FIG. 10D may be substantially the same as that described with reference to FIG. 5C.

Referring to FIG. 10E, a connection state 10b_PS65 of the components included in the power supply device 10b is illustrated with respect to the fifth phase PS65, and an operation related thereto is illustrated.

As described with reference to FIG. 9, in the fifth phase PS65, the third and fourth transistors TR3 and TR4 may be turned on, and an inductor current may flow to the output node NOUT through the inductor L. The intermediate voltage VSW and the output voltage VOUT may be formed by the inductor current.

Referring to FIG. 10F, a connection state 10b_PS66 of the components included in the power supply device 10b is illustrated with respect to the sixth phase PS66, and an operation related thereto is illustrated. FIG. 10F may be substantially the same as that described with reference to FIG. 5D.

For example, in the first phase PS61 and the fourth phase PS64 illustrated in FIGS. 10A and 10D, the output voltage VOUT may be generated based on the inductor current of the inductor L and the capacitor current of the hybrid capacitor CHYBRID that are obtained by the dual path operation. In the second phase PS62 and the fifth phase PS65 illustrated in FIGS. 10B and 10E, the output voltage VOUT may be generated based on the inductor current of the inductor L. In the third phase PS63 and the sixth phase PS66 illustrated in FIGS. 10C and 10F, the output voltage VOUT may be generated based on the capacitor current of the hybrid capacitor CHYBRID. For example, the inductor current and the capacitor current in the first phase PS61 may be collectively referred to as a first current, the inductor current in the second phase PS62 may be referred to as a second current, the capacitor current in the third phase PS63 may be referred to as a third current, the inductor current and the capacitor current in the fourth phase PS64 may be collectively referred to as a fourth current, the inductor current in the fifth phase PS65 may be referred to as a fifth current, and the capacitor current in the sixth phase PS66 may be referred to as a sixth current.

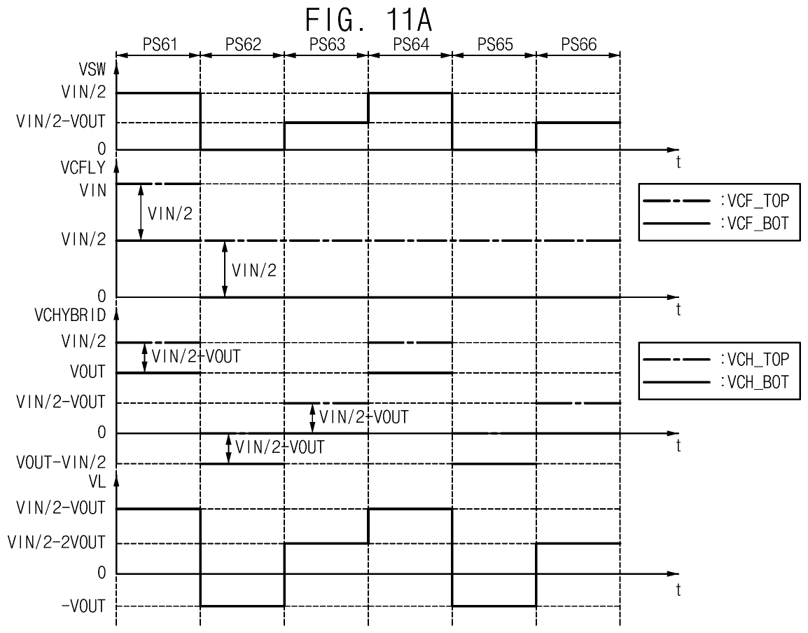

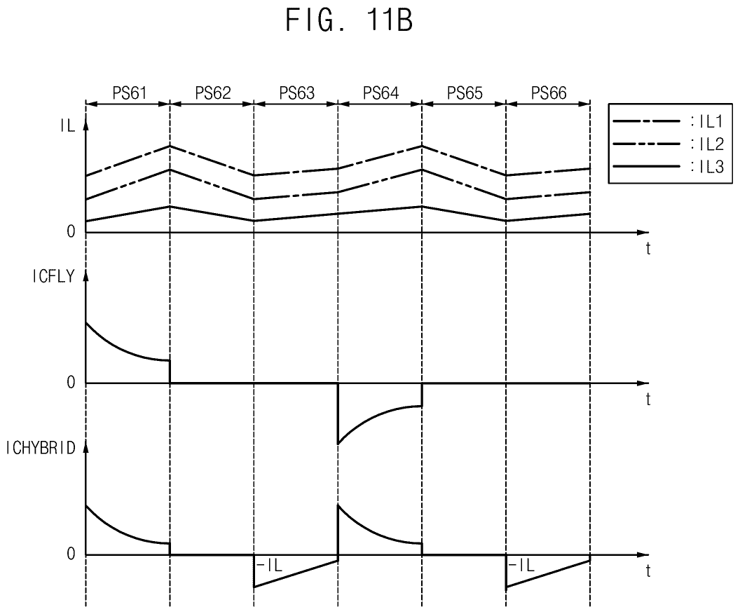

Referring to FIG. 11A, changes in the intermediate voltage VSW, the voltage VCFLY of the flying capacitor CFLY, the voltage VCHYBRID of the hybrid capacitor CHYBRID and the voltage VL of the inductor L are illustrated in the first, second, third, fourth, fifth and sixth phases PS61, PS62, PS63, PS64, PS65 and PS66.

Operations in the first, third, fourth and sixth phases PS61, PS63, PS64 and PS66 may be substantially the same as the operations in the first, second, third and fourth phases PS41, PS42, PS43 and PS44 in FIG. 6A, respectively.

In the second and fifth phases P62 and P65, the voltage level of the voltage VCF_TOP at the first electrode of the flying capacitor CFLY may be substantially equal to a half (e.g., VIN/2) of the voltage level of the input voltage VIN, and the voltage level of the voltage VCF_BOT at the second electrode of the flying capacitor CFLY may be substantially equal to the voltage level (e.g., about 0V) of the ground voltage GND. Therefore, in all of the first, second, third, fourth, fifth and sixth phases PS61, PS62, PS63, PS64, PS65 and PS66, the difference in the voltage levels between the first and second electrodes of the flying capacitor CFLY may be maintained to about VIN/2.

In the second and fifth phases P62 and P65, the voltage level of the intermediate voltage VSW may be substantially equal to the voltage level (e.g., about 0V) of the ground voltage GND.

In the second and fifth phases P62 and P65, the voltage level of the voltage VCH_TOP at the first electrode of the hybrid capacitor CHYBRID may be substantially equal to the voltage level (e.g., about 0V) of the ground voltage GND, and the voltage level of the voltage VCH_BOT at the second electrode of the hybrid capacitor CHYBRID may be substantially equal to a difference (e.g., VOUT-VIN/2) between the voltage level of the output voltage VOUT and a half of the voltage level of the input voltage VIN. Therefore, in all of the first, second, third, fourth, fifth and sixth phases PS61, PS62, PS63, PS64, PS65 and PS66, the difference in the voltage levels between the first and second electrodes of the hybrid capacitor CHYBRID may be maintained to about VIN/2−VOUT.

In the second and fifth phases P62 and P65, the voltage level of the voltage VL of the inductor L may be substantially equal to a voltage level (e.g., −VOUT) that is obtained by multiplying the voltage level of the output voltage VOUT by −1.

Referring to FIG. 11B, changes in the current IL of the inductor L, the current ICFLY of the flying capacitor CFLY and the current ICHYBRID of the hybrid capacitor CHYBRID are illustrated in the first, second, third, fourth, fifth and sixth phases PS61, PS62, PS63, PS64, PS65 and PS66.

Operations in the first, third, fourth and sixth phases PS61, PS63, PS64 and PS66 may be substantially the same as the operations in the first, second, third and fourth phases PS41, PS42, PS43 and PS44 in FIG. 6B, respectively.

As with that described with reference to FIG. 6B, in ‘IL3’, it can be seen that the DC component and the AC component decrease, as compared with ‘IL1’ and ‘IL2’. The current ICFLY of the flying capacitor CFLY and the current ICHYBRID of the hybrid capacitor CHYBRID may vary or may be changed as illustrated in FIG. 11B.

FIGS. 12A and 12B are diagrams illustrating an operation of a power supply device of FIG. 3.

Referring to FIG. 12A, an operating region (or range) and an operation mode of the power supply device 10b may be determined based on a conversion ratio obtained by dividing the output voltage VOUT by the input voltage VIN.

For example, the power supply device 10b may be implemented in the form of a buck converter or a step-down converter, and thus the conversion ratio of the power supply device 10b may be greater than zero and less than or equal to one.

In some example embodiments, the operating region of the power supply device 10b may be in a range where the conversion ratio is greater than zero and less than or equal to a first value CRL. For example, when the conversion ratio is greater than the first value CRL and less than or equal to one, the power supply device 10b may not operate normally (e.g., the power supply device 10b may be in a non-operation region NOP).

In some example embodiments, the first value CRL may be about 0.5. However, some example embodiments are not limited thereto. For example, the first value CRL may be an arbitrary real number greater than zero and less than or equal to one. For example, the operating region of the power supply device 10b may be in a range where the conversion ratio is greater than a second value, which is less than the first value CRL and greater than zero, and less than or equal to the first value CRL.

In some example embodiments, when the conversion ratio is greater than a reference value CRREF within the operating region of the power supply device 10b, the operation mode may be determined as a first operation mode, and the power supply device 10b may operate in a four-phase scheme OP_4P described with reference to FIGS. 4 through 6B. When the conversion ratio is less than or equal to the reference value CRREF within the operating region of the power supply device 10b, the operation mode may be determined as a second operation mode, and the power supply device 10b may operate in a six-phase scheme OP_6P described with reference to FIGS. 9 through 11B.

In some example embodiments, the reference value CRREF may be about 0.25. However, some example embodiments are not limited thereto. For example, the reference value CRREF may be an arbitrary real number greater than zero and less than the first value CRL.

Referring to FIG. 12B, an inductor RMS current INDUCTOR_RMS_I of four different types of converters is illustrated depending on an output voltage of four different types of converters.

As described with reference to FIGS. 7A, 7B, 7C and 7D, ‘CASE1’ may represent a case of a conventional buck converter that performs neither the three-level operation nor the dual path operation, ‘CASE2’ may represent a case of a buck converter that only performs the dual path operation, ‘CASE3’ may represent a case of a buck converter that only performs the three-level operation, and ‘CASE4’ may represent a case of a buck converter according to some example embodiments that performs both the three-level operation and the dual path operation. FIG. 12B illustrates an example where a load current is about 2 A with respect to all converters.

In ‘CASE4’, it can be seen that the inductor RMS current decreases, as compared with ‘CASE1’, ‘CASE2’ and ‘CASE3’. In ‘CASE4’, it can be seen that the operation mode changes based on the conversion ratio of about 25% in a section where the conversion ratio is from about 0% to about 50%. For example, when the input voltage VIN is about 5V, the operation mode may be determined as the second operation mode and the buck converter according to some example embodiments may operate in the six-phase scheme OP_6P, in a section where the output voltage VOUT is from about 0V to about 1.25V (e.g., in a section where the conversion ratio is from about 0% to about 25%). For example, when the input voltage VIN is about 5V, the operation mode may be determined as the first operation mode and the buck converter according to example some example embodiments may operates in the four-phase scheme OP_4P, in a section where the output voltage VOUT is from about 1.25V to about 2.5V (e.g., in a section where the conversion ratio is from about 25% to about 50%).

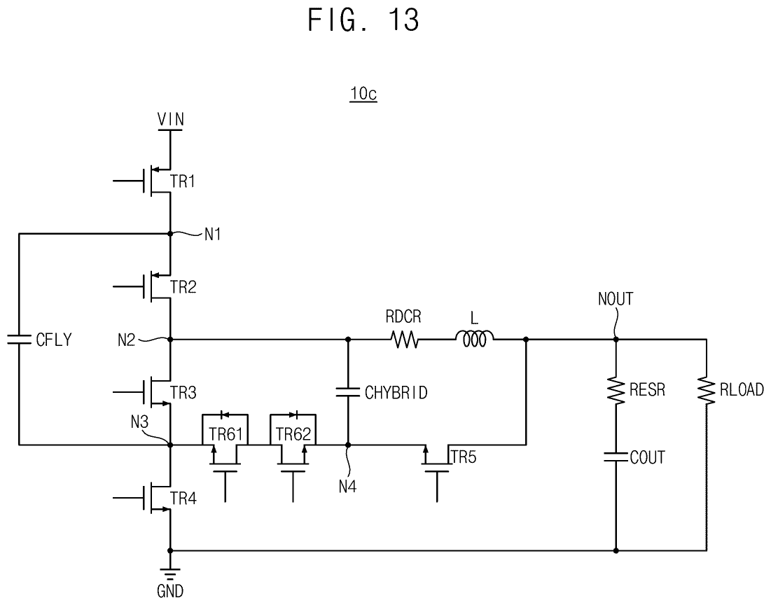

FIG. 13 is a circuit diagram illustrating an example of a power supply device of FIG. 2. The descriptions repeating or overlapping with descriptions of FIG. 3 will be omitted in the interest of brevity.

Referring to FIG. 13, a power supply device 10c may include a first transistor TR1, a second transistor TR2, a third transistor TR3, a fourth transistor TR4, a fifth transistor TR5, a sixth transistor TR61, a seventh transistor TR62, the flying capacitor CFLY, the inductor L, the hybrid capacitor CHYBRID and the output capacitor COUT.

The power supply device 10c may be substantially the same as the power supply device 10b of FIG. 3, except that the sixth transistor TR6 in FIG. 3 is changed to the sixth and seventh transistors TR61 and TR62.

The sixth and seventh transistors TR61 and TR62 may be connected in series between the third node N3 and the fourth node N4, and may be implemented such that a body bias voltage of each of the sixth and seventh transistors TR61 and TR62 is fixed (e.g., such that a body selection is not performed on the sixth and seventh transistors TR61 and TR62). The sixth and seventh transistors TR61 and TR62 may correspond to the sixth switch S6 in FIG. 2, and the third control signal CS3 in FIG. 2 may be applied to gate electrodes of the sixth and seventh transistors TR61 and TR62.

An operation of the sixth and seventh transistors TR61 and TR62 may be substantially the same as the operation of the sixth transistor TR6 in the four-phase scheme described with reference to FIGS. 4 through 6B and the six-phase scheme described with reference to FIGS. 9 through 11B. As illustrated in FIG. 13, the sixth and seventh transistors TR61 and TR62 may be arranged in opposite directions, and they may limit and/or prevent the capacitor current from unintentionally leaking toward the ground voltage GND due to a parasitic diode, even without the body selection. For example, the sixth and seventh transistors TR61 and TR62 may be NMOS transistors.

The power supply device 10c may include seven transistors TR1, TR2, TR3, TR4, TR5, TR61 and TR62, three capacitors CFLY, CHYBRID and COUT, and one inductor L.

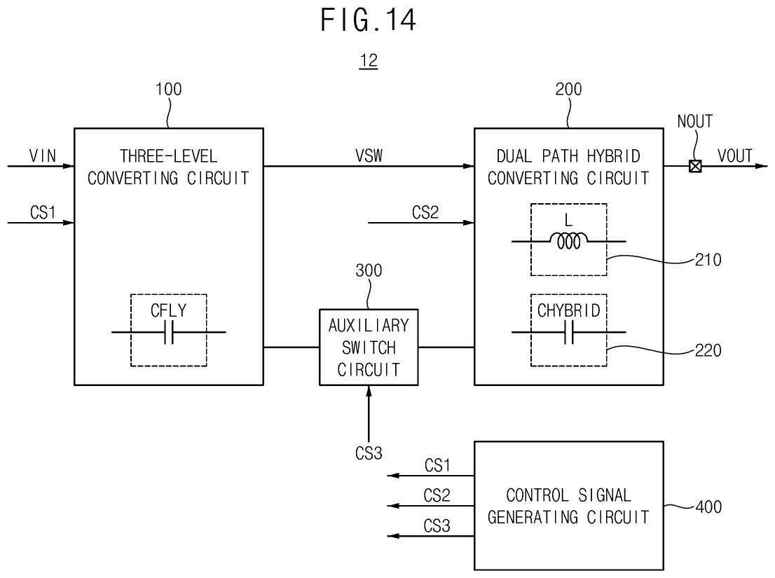

FIG. 14 is a block diagram illustrating a power supply device according to some example embodiments. The descriptions repeating or overlapping with descriptions of FIG. 1 will be omitted in the interest of brevity.

Referring to FIG. 14, a power supply device 12 includes a three-level converting circuit 100, a dual path hybrid converting circuit 200 and an auxiliary switch circuit 300. The power supply device 12 may further include a control signal generating circuit 400.

The power supply device 12 may be substantially the same as the power supply device 10 of FIG. 1, except that the power supply device 12 further includes the control signal generating circuit 400.

The control signal generating circuit 400 may generate the plurality of first control signals CS1, the second control signal CS2 and the third control signal CS3.

In some example embodiments, the three-level converting circuit 100, the dual path hybrid converting circuit 200 and the auxiliary switch circuit 300 may form a power domain, and the control signal generating circuit 400 may form a control domain.

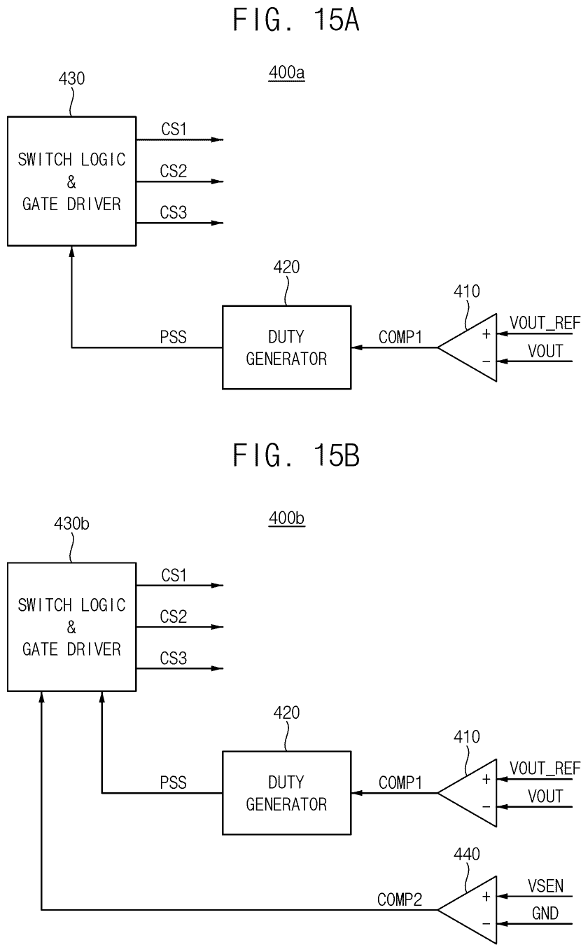

FIGS. 15A and 15B are block diagrams illustrating examples of a control signal generating circuit included in a power supply device of FIG. 14.

Referring to FIG. 15A, a control signal generating circuit 400a may include a first comparator 410, a duty generator 420, and a switch logic and gate driver 430.

The first comparator 410 may generate a first signal COMP1 by comparing the output voltage VOUT with a reference voltage VOUT_REF. The output voltage VOUT may be fed back from the output node NOUT. The duty generator 420 may generate a plurality of phase signals PSS based on the first signal COMP1.

In some example embodiments, when the power supply device 12 operates in the four-phase scheme described with reference to FIGS. 4 through 6B, the plurality of phase signals PSS may include information associated with the first, second, third and fourth phases PS41, PS42, PS43 and PS44 of the four-phase scheme. In some example embodiments, when the power supply device 12 operates in the six-phase scheme described with reference to FIGS. 9 through 11B, the plurality of phase signals PSS may include information associated with the first, second, third, fourth, fifth and sixth phases PS61, PS62, PS63, PS64, PS65 and PS66 of the six-phase scheme.

In some example embodiments, the power supply device 12 may operate in the four-phase scheme or the six-phase scheme based on a result of comparing the output voltage VOUT with the reference voltage VOUT_REF. For example, when the voltage level of the output voltage VOUT is higher than a voltage level of the reference voltage VOUT_REF, the power supply device 12 may operate in the four-phase scheme. For example, when the voltage level of the output voltage VOUT is lower than or equal to the voltage level of the reference voltage VOUT_REF, the power supply device 12 may operate in the six-phase scheme. For example, as described with reference to FIG. 12B, when the output voltage VOUT has a voltage level ranging from about 0V to about 2.5V, the voltage level of the reference voltage VOUT_REF may be about 1.25V.

The switch logic and gate driver 430 may generate the plurality of first control signals CS1, the second control signal CS2 and the third control signal CS3 based on the plurality of phase signals PSS. For example, the plurality of first control signals CS1 may include the control signals CS11, CS12, CS13 and CS14. For example, the control signals CS11, CS12, CS13, CS14, CS2 and CS3 may be applied to the gate electrodes of the transistors TR1, TR2, TR3, TR4, TR5, TR6, TR61 and TR62, and may be used to turn on and off the transistors TR1, TR2, TR3, TR4, TR5, TR6, TR61 and TR62, as illustrated in FIGS. 4 through 5D or FIGS. 9 through 10F.

Referring to FIG. 15B, a control signal generating circuit 400b may include a first comparator 410, a duty generator 420, a switch logic and gate driver 430b, and a second comparator 440.

The control signal generating circuit 400b may be substantially the same as the control signal generating circuit 400a of FIG. 15A, except that the control signal generating circuit 400b further includes the second comparator 440 and an operation of the switch logic and gate driver 430b is partially changed.

The second comparator 440 may generate a second signal COMP2 by comparing the ground voltage GND with a sensing voltage VSEN. The second signal COMP2 may represent whether the current flowing through the inductor Lis zero. The sensing voltage VSEN may be provided from the dual path hybrid converting circuit 200. The switch logic and gate driver 430b may generate the plurality of first control signals CS1, the second control signal CS2 and the third control signal CS3 based on the second signal COMP2 and the plurality of phase signals PSS.

When the current flowing through the inductor L becomes less than zero, e.g., when a direction of the current flowing through the inductor L is changed (or reversed) to the opposite direction, a current may flow from the output node NOUT to the ground voltage GND, and the converter efficiency may be degraded or deteriorated. Therefore, to limit and/or prevent a situation where the direction of the current flowing through the inductor L is changed, the moment when the current flowing through the inductor L becomes zero may be detected, and then the control signals CS1, CS2 and CS3 and the operations of the transistors TR1, TR2, TR3, TR4, TR5, TR6, TR61 and TR62 may be controlled or adjusted.

In some example embodiments, the sensing voltage VSEN may be provided from a node (e.g., the fourth node N4 in FIGS. 2 and 3) that is directly connected to the hybrid capacitor CHYBRID and the auxiliary switch circuit 300, rather than a node (e.g., the second node N2 in FIGS. 2 and 3) that is directly connected to the inductor L.

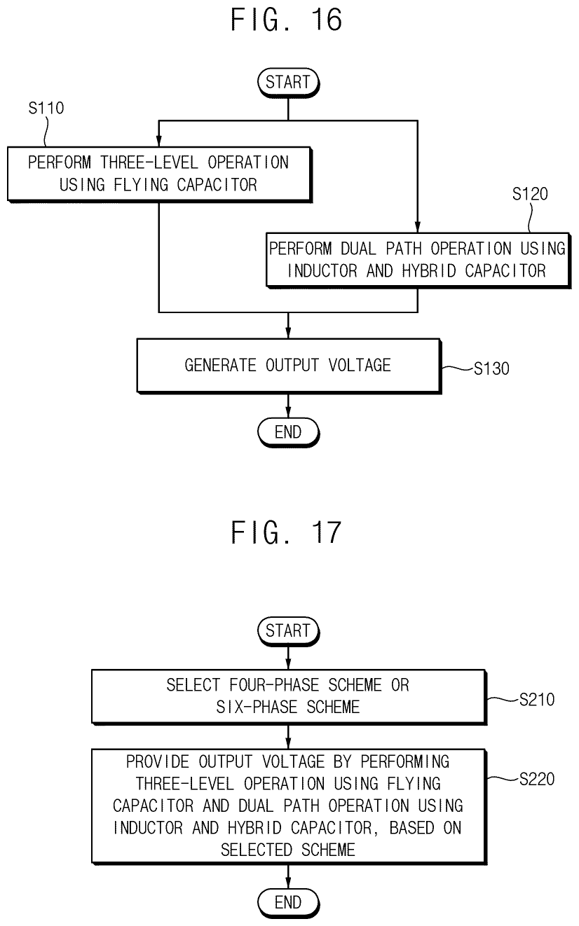

FIGS. 16 and 17 are flowcharts illustrating a method of operating a power supply device according to some example embodiments.

Referring to FIGS. 1 and 16, in a method of operating a power supply device according to some example embodiments, the three-level operation is performed using the flying capacitor CFLY (operation S110), the dual path operation is performed using the inductor L included in the first path 210 and the hybrid capacitor CHYBRID included in the second path 220 (operation S120), and the output voltage VOUT is generated based on the three-level operation and the dual path operation (operation S130). In some example embodiments, operations S110 and S120 may be performed substantially simultaneously or concurrently. In some example embodiments, operations S110 and S120 may be performed sequentially and/or alternately. For example, the power supply device may be implemented as described with reference to FIGS. 1 through 3 and 13 through 15B, and may operate as described with reference to FIGS. 4 through 12B.

Referring to FIGS. 1 and 17, in a method of operating a power supply device according to some example embodiments, the four-phase scheme or the six-phase scheme is selected (operation S210), and the output voltage VOUT is provided by performing the three-level operation using the flying capacitor CFLY and the dual path operation using the inductor L and the hybrid capacitor CHYBRID, based on the selected scheme among the four-phase and six-phase schemes (operation S220). For example, in operation S210, the four-phase scheme or the six-phase scheme may be selected based on the conversion ratio, as described with reference to FIG. 12A. For example, in operation S220, the power supply device may operate as described with reference to FIGS. 4 through 6B when the four-phase scheme is selected, and the power supply device may operate as described with reference to FIGS. 9 through 11B when the six-phase scheme is selected. For example, operation S220 may include operations S110, S120 and S130 in FIG. 16.

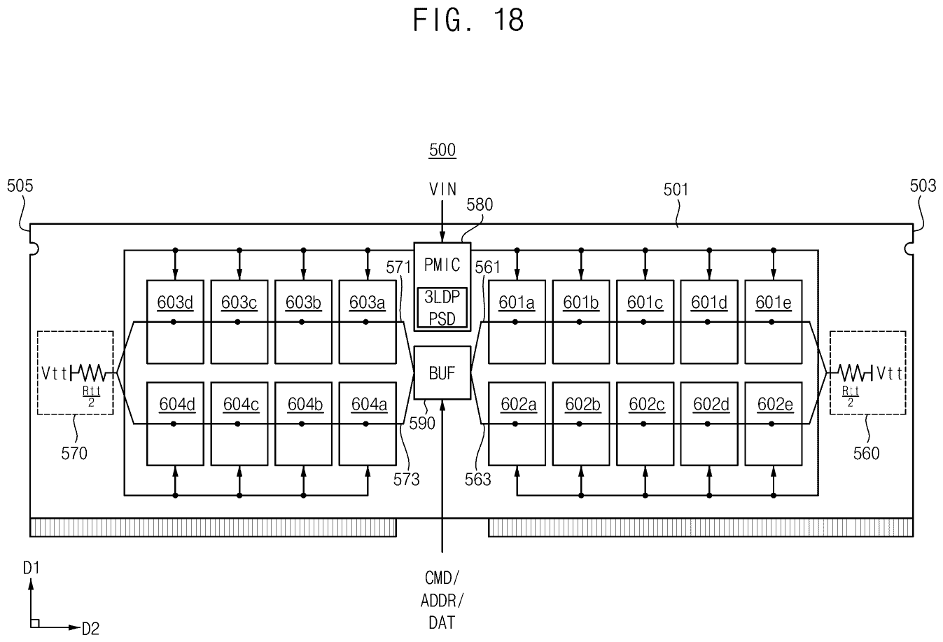

FIG. 18 is a block diagram illustrating a memory module according to some example embodiments.

Referring to FIG. 18, a memory module 500 may include a circuit board 501, a plurality of memory devices 601a, 601b, 601c, 601d, 601e, 602a, 602b, 602c, 602d, 602e, 603a, 603b, 603c, 603d, 604a, 604b, 604c and 604d, and a power management integrated circuit (PMIC) 580. The memory module 500 may further include a buffer chip 590 (e.g., a registered clock driver; RCD) and module resistance units 560 and 570. For example, the plurality of memory devices 601a to 601e, 602a to 602e, 603a to 603d and 604a to 604d, the PMIC 580, the buffer chip 590 and/or the module resistance units 560 and 570 may be disposed, arranged or mounted on or in the circuit board 501.

The buffer chip 590 may control the plurality of memory devices 601a to 601e, 602a to 602e, 603a to 603d and 604a to 604d, and the PMIC 580, under a control of a memory controller that is located outside the memory module 500. For example, the buffer chip 590 may receive an address ADDR, a command CMD and data DAT from the memory controller.

The circuit board 501 may extend in a second direction D2, perpendicular to a first direction D1, between a first edge portion 503 and a second edge portion 505. The first edge portion 503 and the second edge portion 505 may extend in the first direction D1. For example, the circuit board 501 may be a printed circuit board (PCB). The buffer chip 590 may be arranged on a center of the circuit board 501. The memory devices 601a to 601e and 602a to 602e may be arranged in or along a plurality of rows between the buffer chip 590 and the first edge portion 503, and the memory devices 603a to 603d and 604a to 604d may be arranged in or along a plurality of rows between the buffer chip 590 and the second edge portion 505.

The buffer chip 590 may store the data DAT in the plurality of memory devices 601a to 601e, 602a to 602e, 603a to 603d and 604a to 604d. The buffer chip 590 may provide a command/address (CA) signal (e.g., corresponding to the command CMD and the address ADDR) to the plurality of memory devices 601a to 601e, 602a to 602e, 603a to 603d and 604a to 604d through CA transmission lines 561, 563, 571 and 573. In some example embodiments, operations described herein as being performed by the buffer chip 590 may be performed by processing circuitry.

The CA transmission lines 561 and 563 may be connected in common to the module resistance unit 560 that is adjacent to the first edge portion 503, and the CA transmission lines 571 and 573 may be connected in common to the module resistance unit 570 that is adjacent to the second edge portion 505. Each of the module resistance units 560 and 570 may include a termination resistor Rtt/2 connected to a termination voltage Vtt.

For example, each of or at least one of the plurality of memory devices 601a to 601e, 602a to 602e, 603a to 603d and 604a to 604d may be or include a DRAM device.

The PMIC 580 may be disposed to be adjacent to the buffer chip 590. The PMIC 580 may generate a power supply voltage VDD based on an input voltage VIN, and may provide the power supply voltage VDD to the plurality of memory devices 601a to 601e, 602a to 602e, 603a to 603d and 604a to 604d.

The PMIC 580 may include a power supply device 3LDP PSD. The power supply device 3LDP PSD may be the power supply device according to some example embodiments of the inventive concepts. For example, the power supply device 3LDP PSD may generate the output voltage VOUT corresponding to the power supply voltage VDD by performing both the three-level operation and the dual path operation. Accordingly, the loss due to the DC resistance of the inductor may be reduced even if the physical size of the inductor is reduced, and the additional space that is obtained by reducing the physical size of the inductor may be utilized for other components (e.g., to increase the physical size of the capacitor).

Although not illustrated in FIG. 18, the memory module 500 may further include a serial present detection (SPD) chip. For example, the SPD chip may include device information and/or initial information of the memory module 500, such as a module form, a module configuration, a storage capacity, a module type, an execution environment, and/or the like of the memory module 500. When a memory system including the memory module 500 including the SPD chip is booted up, the device information may be read or retrieved from the SPD chip, and the memory module 500 may be recognized, identified and/or controlled based on the device information.

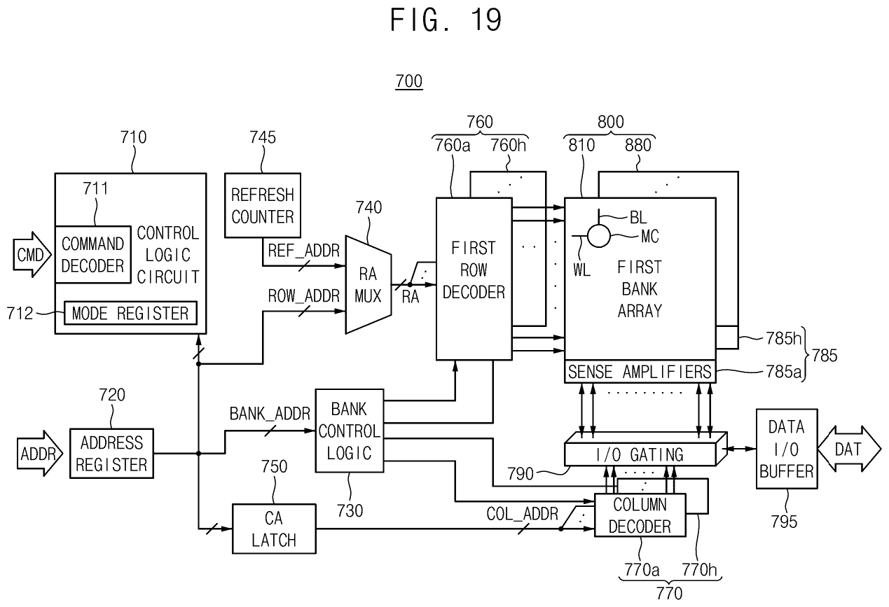

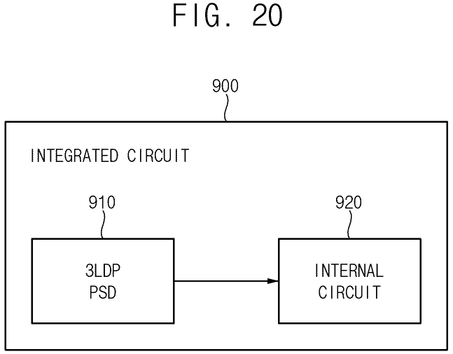

FIG. 19 is a block diagram illustrating an example of a memory device included in a memory module according to some example embodiments of the inventive concepts.

Referring to FIG. 19, a memory device 700 may include a control logic circuit 710, an address register 720, a bank control logic circuit 730, a row address multiplexer 740, a refresh counter 745, a column address latch 750, a row decoder 760, a column decoder 770, a memory cell array 800, a sense amplifier unit 785, an input/output (I/O) gating circuit 790 and a data I/O buffer 795. For example, the memory device 700 may be one of various volatile memory devices such as a DRAM device.

The memory cell array 800 may include first to eighth bank arrays 810 to 880 (e.g., first to eighth bank arrays 810, 820, 830, 840, 850, 860, 870 and 880). The row decoder 760 may include first to eighth bank row decoders 760a to 760h connected respectively to the first to eighth bank arrays 810 to 880. The column decoder 770 may include first to eighth bank column decoders 770a to 770h connected respectively to the first to eighth bank arrays 810 to 880. The sense amplifier unit 785 may include first to eighth bank sense amplifiers 785a to 785h connected respectively to the first to eighth bank arrays 810 to 880.

The first to eighth bank arrays 810 to 880, the first to eighth bank row decoders 760a to 760h, the first to eighth bank column decoders 770a to 770h, and the first to eighth bank sense amplifiers 785a to 785h may form first to eighth banks. Each of the first to eighth bank arrays 810 to 880 may include a plurality of wordlines WL, a plurality of bitlines BL, and a plurality of memory cells MC that are at intersections of the wordlines WL and the bitlines BL.

Although FIG. 19 illustrates the memory device 700 including eight banks (and eight bank arrays, eight row decoders, and so on), the memory device 700 may include any number of banks; for example, one, two, four, eight, sixteen, or thirty two banks, or any number therebetween one and thirty two.

The address register 720 may receive the address ADDR including a bank address BANK_ADDR, a row address ROW_ADDR, and a column address COL_ADDR from a memory controller that is located outside the memory device 700. The address register 720 may provide the received bank address BANK_ADDR to the bank control logic circuit 730, may provide the received row address ROW_ADDR to the row address multiplexer 740, and may provide the received column address COL_ADDR to the column address latch 750.

The bank control logic circuit 730 may generate bank control signals in response to the bank address BANK_ADDR. One of the first to eighth bank row decoders 760a to 760h corresponding to the bank address BANK_ADDR may be activated in response to the bank control signals, and one of the first to eighth bank column decoders 770a to 770h corresponding to the bank address BANK_ADDR may be activated in response to the bank control signals.

The row address multiplexer 740 may receive the row address ROW_ADDR from the address register 720, and may receive a refresh row address REF_ADDR from the refresh counter 745. The row address multiplexer 740 may selectively output the row address ROW_ADDR or the refresh row address REF_ADDR as a row address RA. The row address RA that is output from the row address multiplexer 740 may be applied to the first to eighth bank row decoders 760a to 760h.

The activated one of the first to eighth bank row decoders 760a to 760h may decode the row address RA that is output from the row address multiplexer 740, and may activate in the corresponding bank array a wordline WL corresponding to the row address RA. For example, the activated bank row decoder may generate a wordline driving voltage, and may apply the wordline driving voltage to the wordline WL corresponding to the row address RA.

The column address latch 750 may receive the column address COL_ADDR from the address register 720, and may temporarily store the received column address COL_ADDR. In some example embodiments, in a burst mode, the column address latch 750 may generate column addresses that increment from the received column address COL_ADDR. The column address latch 750 may apply the temporarily stored or generated column address to the first to eighth bank column decoders 770a to 770h.

The activated one of the first to eighth bank column decoders 770a to 770h may decode the column address COL_ADDR that is output from the column address latch 750, and may control the I/O gating circuit 790 to output data corresponding to the column address COL_ADDR.

The I/O gating circuit 790 may include circuitry configured to gate input/output data. The I/O gating circuit 790 may further include read data latches configured to store data that is output from the first to eighth bank arrays 810 to 880, and may also include write control devices for writing data to the first to eighth bank arrays 810 to 880.

Data DAT read from one of the first to eighth bank arrays 810 to 880 may be sensed by a sense amplifier connected to the one bank array from which the data DAT is to be read, and may be stored in the read data latches. The data DAT stored in the read data latches may be provided to the memory controller via the data I/O buffer 795. Data DAT to be written in one of the first to eighth bank arrays 810 to 880 may be provided to the I/O gating circuit 790 via the data I/O buffer 795 from the memory controller, and the I/O gating circuit 790 may write the data DAT in the one bank array through the write drivers.

The control logic circuit 710 may control operations of the memory device 700. For example, the control logic circuit 710 may generate control signals for the memory device 700 to perform the write operation and/or the read operation. The control logic circuit 710 may include a command decoder 711 that decodes a command CMD received from the memory controller, and a mode register 712 that sets an operation mode of the memory device 700. In some example embodiments, operations described herein as being performed by the control logic circuit 710 may be performed by processing circuitry. For example, the command decoder 711 may generate the control signals corresponding to the command CMD by decoding a write enable signal, a row address strobe signal, a column address strobe signal, a chip selection signal, etc.

FIG. 20 is a block diagram illustrating an integrated circuit including a power supply device according to some example embodiments.

Referring to FIG. 20, an integrated circuit 900 includes a power supply device (3LDP PSD) 910 and an internal circuit 920.

The power supply device 910 may be the power supply device according to some example embodiments. For example, the power supply device 910 may generate the output voltage VOUT by performing both the three-level operation and the dual path operation. Accordingly, the loss due to the DC resistance of the inductor may be reduced even if the physical size of the inductor is reduced, and the additional space that is obtained by reducing the physical size of the inductor may be utilized for other components (e.g., for increasing the physical size of the capacitor). The internal circuit 920 may perform a specific (e.g., desired and/or predetermined) operation based on the output voltage (or power supply voltage) VOUT provided from the power supply device 910.

The example embodiments may be applied to various electronic devices and systems that include the power supply devices. For example, some example embodiments may be applied to systems such as a personal computer (PC), a server computer, a data center, a workstation, a mobile phone, a smart phone, a tablet computer, a laptop computer, a personal digital assistant (PDA), a portable multimedia player (PMP), a digital camera, a portable game console, a music player, a camcorder, a video player, a navigation device, a wearable device, an internet of things (IoT) device, an internet of everything (IoE) device, an e-book reader, a virtual reality (VR) device, an augmented reality (AR) device, a robotic device, a drone, automotive, etc.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, an application-specific integrated circuit (ASIC), etc.

The foregoing is illustrative of example embodiments and is not to be construed as limiting thereof. Although some example embodiments have been described, those skilled in the art will readily appreciate that many modifications are possible in the example embodiments without materially departing from the novel teachings and advantages of the example embodiments. Accordingly, all such modifications are intended to be included within the scope of the example embodiments as defined in the claims. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A power supply device comprising:
a three-level converting circuit including a flying capacitor configured for three-level operation, the three-level converting circuit configured to generate an intermediate voltage based on an input voltage, a plurality of first control signals and the flying capacitor;
a dual path hybrid converting circuit including a first path, a second path, an inductor in the first path and a hybrid capacitor in the second path, the dual path hybrid converting circuit configured to generate an output voltage based on the intermediate voltage, a second control signal, the inductor and the hybrid capacitor,
both the first path and the second path being connected to an output node providing the output voltage, the first path and the second path being different from each other; and
an auxiliary switch circuit between the three-level converting circuit and the dual path hybrid converting circuit, the auxiliary switch circuit configured to control current flow through the hybrid capacitor based on a third control signal,
wherein the power supply device is configured to selectively operate based on a four-phase scheme and a six-phase scheme depending on an operation mode.

2. The power supply device of claim 1,
wherein the four-phase scheme includes a first phase, a second phase, a third phase and a fourth phase, and
the power supply device is configured responsive to the plurality of first control signals, the second control signal and the third control signal to
operate during the first phase wherein the flying capacitor is charged, and a first current flows through the inductor and the hybrid capacitor,
operate during the second phase wherein a second current flows through the hybrid capacitor,
operate during the third phase wherein the flying capacitor is discharged, and a third current flows through the inductor and the hybrid capacitor, and
operate during the fourth phase wherein a fourth current flows through the hybrid capacitor.

3. The power supply device of claim 1,
wherein the six-phase scheme includes a first phase, a second phase, a third phase, a fourth phase, a fifth phase and a sixth phase, and
the power supply device is configured responsive to the plurality of first control signals, the second control signal and the third control signal to
operate during the first phase wherein the flying capacitor is charged, and a first current flows through the inductor and the hybrid capacitor,
operate during the second phase wherein a second current flows through the inductor,
operate during the third phase wherein a third current flows through the hybrid capacitor,
operate during the fourth phase wherein the flying capacitor is discharged, and a fourth current flows through the inductor and the hybrid capacitor,
operate during the fifth phase wherein a fifth current flows through the inductor, and
operate during the sixth phase wherein a sixth current flows through the hybrid capacitor.

4. The power supply device of claim 1, wherein the three-level converting circuit further comprises:
a first transistor connected between the input voltage and a first node;
a second transistor connected between the first node and a second node;
a third transistor connected between the second node and a third node; and
a fourth transistor connected between the third node and a ground voltage, and
wherein the flying capacitor is connected between the first node and the third node.

5. The power supply device of claim 4, wherein the dual path hybrid converting circuit further comprises:
a fifth transistor connected between a fourth node and the output node,
wherein the inductor is connected between the second node and the output node, and
wherein the hybrid capacitor is connected between the second node and the fourth node.

6. The power supply device of claim 5, wherein the auxiliary switch circuit comprises:
a sixth transistor connected between the third node and the fourth node, and a body bias voltage applied to the sixth transistor being changeable.

7. The power supply device of claim 6,
wherein the four-phase scheme includes a first phase, a second phase, a third phase and a fourth phase, and
the power supply device is configured responsive to the plurality of first control signals, the second control signal and the third control signal to
operate during the first phase wherein the first, third and fifth transistors are turned on, and the second, fourth and sixth transistors are turned off,
operate during the second phase wherein the fourth and sixth transistors are turned on, and the first, second, third and fifth transistors are turned off,
operate during the third phase wherein the second, fourth and fifth transistors are turned on, and the first, third and sixth transistors are turned off, and
operate during the fourth phase wherein the fourth and sixth transistors are turned on, and the first, second, third and fifth transistors are turned off.

8. The power supply device of claim 6,
wherein the six-phase scheme includes a first phase, a second phase, a third phase, a fourth phase, a fifth phase and a sixth phase, and
the power supply device is configured responsive to the plurality of first control signals, the second control signal and the third control signal to
operate during the first phase wherein the first, third and fifth transistors are turned on, and the second, fourth and sixth transistors are turned off,
operate during the second phase wherein the third and fourth transistors are turned on, and the first, second, fifth and sixth transistors are turned off,
operate during the third phase wherein the fourth and sixth transistors are turned on, and the first, second, third and fifth transistors are turned off,
operate during the fourth phase wherein the second, fourth and fifth transistors are turned on, and the first, third and sixth transistors are turned off,
operate during the fifth phase wherein the third and fourth transistors are turned on, and the first, second, fifth and sixth transistors are turned off, and
operate during the sixth phase wherein the fourth and sixth transistors are turned on, and the first, second, third and fifth transistors are turned off.

9. The power supply device of claim 6,
wherein the first and second transistors are p-type metal oxide semiconductor (PMOS) transistors, and
wherein the third, fourth, fifth and sixth transistors are n-type metal oxide semiconductor (NMOS) transistors.

10. The power supply device of claim 5, wherein the auxiliary switch circuit comprises:
a sixth transistor and a seventh transistor connected in series between the third node and the fourth node, and a body bias voltage applied to each of the sixth and seventh transistors being fixed.

11. The power supply device of claim 1, further comprising:
a control signal generating circuit configured to generate the plurality of first control signals, the second control signal and the third control signal.

12. The power supply device of claim 11, wherein the control signal generating circuit comprises:
a first comparator configured to generate a first signal by comparing the output voltage with a reference voltage;
a duty generator configured to generate a plurality of phase signals based on the first signal; and
a switch logic and gate driver configured to generate the plurality of first control signals, the second control signal and the third control signal based on the plurality of phase signals.

13. The power supply device of claim 12, wherein the control signal generating circuit further comprises:
a second comparator configured to generate a second signal by comparing a ground voltage with a sensing voltage provided from the dual path hybrid converting circuit, the second signal representing whether a current flowing through the inductor is zero, and
wherein the switch logic and gate driver is configured to generate the plurality of first control signals, the second control signal and the third control signal based on the plurality of phase signals and the second signal.

14. The power supply device of claim 13, wherein the sensing voltage is provided from a node directly connected to the hybrid capacitor and the auxiliary switch circuit, and not from a node directly connected to the inductor.

15. The power supply device of claim 1, wherein the operation mode is determined based on a conversion ratio obtained by dividing the output voltage by the input voltage.

16. The power supply device of claim 15,
wherein, when the conversion ratio is greater than a reference value within an operating region, the operation mode is determined as a first operation mode and the power supply device operates in the four-phase scheme, and
wherein, when the conversion ratio is less than or equal to the reference value within the operating region, the operation mode is determined as a second operation mode and the power supply device operates in the six-phase scheme.

17. The power supply device of claim 1, wherein a voltage level of the output voltage is lower than a voltage level of the input voltage.

18. A memory module comprising:
a circuit board;
a plurality of memory devices on the circuit board; and
a power supply device on the circuit board, the power supply device configured to provide a power supply voltage to the plurality of memory devices,
wherein the power supply device comprises
a three-level converting circuit including a flying capacitor for three-level operation, the three-level converting circuit configured to generate an intermediate voltage based on an input voltage, a plurality of first control signals and the flying capacitor,
a dual path hybrid converting circuit including a first path, a second path, an inductor in the first path and a hybrid capacitor in the second path, the dual path hybrid converting circuit configured to generate an output voltage based on the intermediate voltage, a second control signal, the inductor and the hybrid capacitor,
both the first path and the second path being connected to an output node providing the output voltage, the first path and the second path being different from each other, the output voltage corresponding to the power supply voltage, and
an auxiliary switch circuit between the three-level converting circuit and the dual path hybrid converting circuit, the auxiliary switch circuit configured to control current flow through the hybrid capacitor based on a third control signal,
wherein the power supply device is configured to selectively operate based on a four-phase scheme and a six-phase scheme depending on an operation mode.

19. The memory module of claim 18, wherein the plurality of memory devices are dynamic random access memory (DRAM) devices.

20. A power supply device comprising:
a first transistor connected between an input voltage and a first node;
a second transistor connected between the first node and a second node, the second node providing an intermediate voltage;
a third transistor connected between the second node and a third node;
a fourth transistor connected between the third node and a ground voltage;
a flying capacitor connected between the first node and the third node;
an inductor connected between the second node and an output node, the output node providing an output voltage;
a hybrid capacitor connected between the second node and a fourth node;
a fifth transistor connected between the fourth node and the output node;
a sixth transistor connected between the third node and the fourth node, and a body bias voltage applied to the sixth transistor being changeable; and
an output capacitor connected between the output node and the ground voltage,
wherein the first, second, third and fourth transistors and the flying capacitor are configured to perform three-level operation,
wherein the inductor is included in a first path, the first path being connected to the output node,
wherein the hybrid capacitor is included in a second path, the second path being connected to the output node,
wherein the power supply device is configured to generate the output voltage using a dual path including the first and second paths, and
wherein the power supply device is configured to selectively operate based on a four-phase scheme and a six-phase scheme based on a conversion ratio obtained by dividing the output voltage by the input voltage.
